(19) United States
(12) Patent Application Publication
(10) Pub. No.: US 2023/0299733 A1
(43) Pub. Date: Sep. 21, 2023

(54) METHODS OF FORMING PIEZOELECTRIC RESONATOR DEVICES INCLUDING EMBEDDED ENERGY CONFINEMENT FRAMES

(71) Applicant: Akoustis, Inc., Huntersville, NC (US)

(72) Inventors: Abhay Saranswarup Kochhar, Charlotte, NC (US); Dae Ho Kim, Cornelius, NC (US); Zhiqiang Bi, Mooresville, NC (US); Emad Mehdizadeh, Charlotte, NC (US); Mojtaba Hodjat-Shamami, Cornelius, NC (US); Mary Winters, Webster, NY (US); Rohan Houlden, Oak Ridge, NC (US); Jeffrey B. Shealy, Cornelius, NC (US)

(21) Appl. No.: 18/185,577

(22) Filed: Mar. 17, 2023

Related U.S. Application Data
(60) Provisional application No. 63/321,308, filed on Mar. 18, 2022.

(30) Foreign Application Priority Data
Mar. 17, 2023 (WO) PCT/US23/64639

(51) Int. Cl. H03H 3/02

(52) U.S. Cl. CPC H03H 3/02

(57) ABSTRACT

A piezoelectric resonator device can be formed to include a piezoelectric film including an active area configured to provide a thickness excited mode of vibration, a first electrode on a first surface of the piezoelectric film positioned to electromechanically couple to the active area, a second electrode on a second surface of the piezoelectric film, opposite the first surface, the second electrode positioned to electromechanically couple to the active area, an energy confinement frame extending on the piezoelectric film embedded in the first or second electrode, an inner side wall of the energy confinement frame facing toward the active area and extending around the active area to define a perimeter that separates the active area located inside the perimeter from an outer area located outside the perimeter adjacent to the active area, an outer side wall of the energy confinement frame facing toward the outer area and aligned to an outer side wall of the first or second electrode and a conformal low-impedance acoustic layer extending on the active area over the energy confinement frame to cover the outer side wall of the energy confinement frame, and onto the piezoelectric film in the outer area.

### CROSS-REFERENCE TO RELATED APPLICATIONS AND CLAIM FOR PRIORITY

The present application claims priority to U.S. Provisional patent application Ser. No. 63/321,308, filed in the USPTO on Mar. 18, 2022, titled Methods of Forming Single Crystal Piezoelectric Resonator Devices Including Energy Confinement Frames and Related Devices, and to PCT Application No. ______ filed on ______ in the USRO, titled Piezoelectric Resonator Devices Including Embedded Energy Confinement Frames, the entire disclosures of which are hereby incorporated herein by reference in their entireties.

### BACKGROUND

Wireless data communications can utilize RF filters operating at frequencies around 5 GHz and higher. It is known to use Bulk acoustic Wave Resonators (BAWR) incorporating piezoelectric thin films for some applications. While some piezoelectric thin film BAWRs may be adequate for filters operating at frequencies from about 1 to 3 GHz, applications at frequencies around 5 GHz and above may present obstacles due to the reduced crystallinity associated with some films.

### BRIEF DESCRIPTION OF THE DRAWINGS

FIGS. 1A-1C through FIGS. 20A-20C are diagrams illustrating various cross-sectional views of a single crystal acoustic resonator device including energy confinement frames and of operations for a transfer process using a sacrificial layer for single crystal acoustic resonator devices according to an example of the present invention.

FIGS. 21 and 22 are cross-sectional views of single crystal piezoelectric resonator devices with resonator cavities and including energy confinement frames in some embodiments according to the present invention.

FIGS. 23A-23C to 39A-39C are diagrams illustrating various cross-sectional views of a single crystal acoustic resonator device including energy confinement frames and of operations for a solidly mounted transfer process for single crystal acoustic resonator devices according to an example of the present invention.

FIGS. 40 and 41 are cross-sectional views of single crystal piezoelectric resonator devices with reflectors and including energy confinement frames in some embodiments according to the present invention.

### SUMMARY

Embodiments according to the present invention can provide methods of forming piezoelectric resonator devices including embedded energy confinement frames. Pursuant to these embodiments, a piezoelectric resonator device can be formed by forming a piezoelectric film on a growth substrate, forming a first electrode on a first surface of the piezoelectric film, forming a support layer on the piezoelectric film and on the first electrode, bonding the support layer to a bond substrate, removing the growth substrate to expose a second surface of the piezoelectric film that is opposite the first surface of the piezoelectric film, forming an energy confinement layer on the second surface of the piezoelectric film, patterning the energy confinement layer to form an energy confinement frame on a portion of the second surface of the piezoelectric film designated as the active region of the piezoelectric resonator device, the energy confinement frame including an outer side wall that faces an outer region of the piezoelectric film outside the active region and an including an inner side wall that extends around a permitter of the active region, forming a second electrode layer extending on the active region conformably over the energy confinement frame onto the outer side wall and onto a portion of the piezoelectric film in the outer region directly adjacent to the energy confinement frame, forming a second electrode on the second surface of the piezoelectric film by removing the second electrode layer and the energy confinement layer from the portion of the piezoelectric film in the outer region directly adjacent to the energy confinement frame so that the outer side wall of the energy confinement frame is aligned with a side wall of the second electrode, and forming a substantially uniform thickness low-impedance acoustic layer over the active area and onto the side wall of the second electrode and onto the portion of the piezoelectric film in the outer region directly adjacent to the energy confinement frame. DETAILED DESCRIPTION OF EMBODIMENTS ACCORDING TO THE PRESENT INVENTION

According to embodiments of the present invention, techniques generally related to electronic devices are provided. More particularly, the present invention provides techniques related to a method of manufacture and structure for bulk acoustic wave resonator devices, single crystal resonator devices, single crystal filter and resonator devices, and the like. Merely by way of example, the invention has been applied to a single crystal resonator device for a communication device, mobile device, computing device, among others.

The present invention provides manufacturing processes and structures for high quality bulk acoustic wave resonators with piezoelectric thin films for high frequency BAW filter and other applications. It will be understood that the piezoelectric resonator devices described herein can be formed to include single crystal materials/layers/films, epitaxial materials/layers/films, textured materials/layers/films, polycrystalline materials/layers/films, or combinations thereof. As used herein, a polycrystalline (sometimes referred to as a poly crystal) film, layer, or material has a random orientation of grains relative to each other. A textured film, layer, or material has grains aligned with one axis, for example with the c-axis, of the crystalline structure perpendicular to material surface. An epitaxial film, layer, or material has grains aligned in their own direction with all the axes, for example, the a-axis, b-axis, and c-axis, of the crystalline structure. A single crystal film, layer, or material has larger grains aligned very well (≤1° or <1°) in their own direction with all the axes, for example, the a-axis, b-axis, and c-axis, of the crystalline structure.

In some embodiments, epitaxial and single crystal piezoelectric films can be formed using an ordered growth process such as CVD, MOCVD, MBE, or the like. Single crystalline or epitaxial piezoelectric thin films grown on compatible crystalline substrates can exhibit good crystalline quality and high piezoelectric performance even down to very thin thicknesses, e.g., 0.4 um or less. The present invention provides manufacturing processes and structures for high quality bulk acoustic wave resonators with single crystalline or epitaxial piezoelectric thin films for high frequency BAW filter applications.

Embodiments according to the present invention can use crystalline piezoelectric films with an embedded energy confinement frame and a thin film transfer processes to produce a BAWR with enhanced ultimate quality factor and electro-mechanical coupling for RF filters. Such methods and structures can facilitate methods of manufacturing and structures for RF filters using crystalline or epitaxial piezoelectric films to meet the growing demands of contemporary data communication.

In some embodiments according to the present invention, a transfer processes for formation of acoustic resonator devices can provide a flat, high-quality, single-crystal piezoelectric film for superior acoustic wave control and high Q at high frequency. Also, growing epitaxial piezoelectric layers on patterned electrodes can affect the crystalline orientation of the piezoelectric layer, which may limit tight boundary control of the resulting resonators.

Embodiments according to the present invention, as further described herein, can overcome these limitations and exhibit improved performance and cost-efficiency. For example, in some embodiments according to the present invention, an energy confinement frame can be embedded within an electrode(s) fabricated using, for example, a transfer process wherein a crystalline piezoelectric film can be formed on a growth substrate along with an electrode (having an optional energy confinement frame embedded therein) and a sacrificial layer (or a reflector) covered by a support layer.

The structures described herein can be processed from the reversed side by attaching the support layer to a bond substrate and then removing the growth substrate to expose the reverse side of the crystalline piezoelectric film. The resonator can be completed by forming another energy confinement frame in (opposite the first optional energy confinement frame) on the exposed surface of the crystalline piezoelectric film and then forming a second electrode followed by the connectivity for the first and second electrodes. Accordingly, in some embodiments according to the present invention, resonator devices can include a first energy confinement frame embedded in the upper electrode and/or a second energy confinement frame embedded in the lower electrode.

In some embodiments according to the present invention, the structures described herein can be covered by a conformal low-impedance acoustic layer that extends over the active region of the resonator, over the energy confinement frame(s), and onto the adjacent surface of the crystalline piezoelectric film that lies in the outer region. The first and second energy confinement frames can be fully recessed within the respective electrode so that the low-impedance acoustic layer that covers the electrode is not layered on the energy confinement frames that lies within the adjacent electrode side wall. The conformal low-impedance acoustic layer can include a passivation material, a metal, or the like.

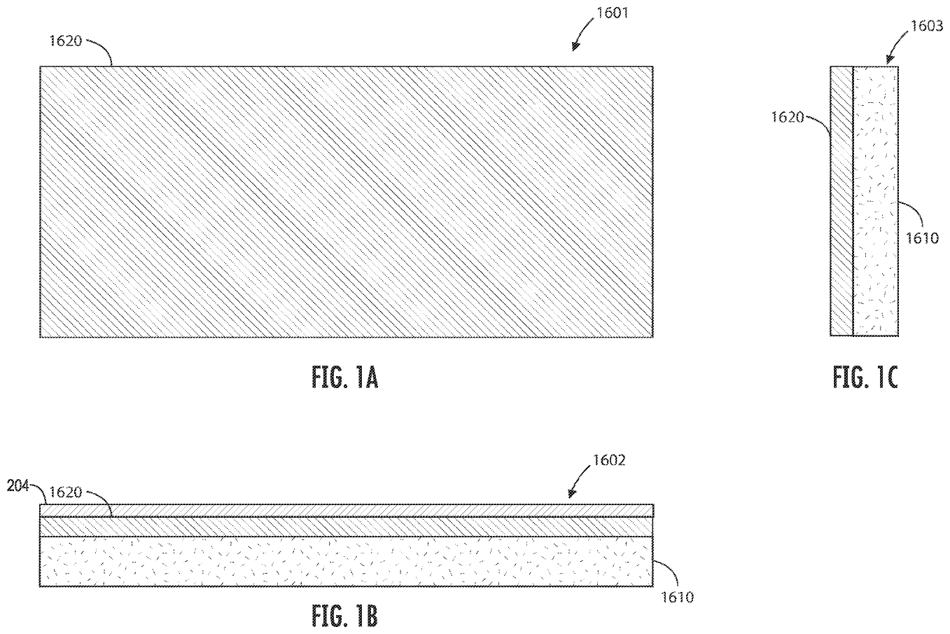

FIGS. 1A-1C through FIGS. 20A-20C illustrate methods of fabrication for an acoustic resonator device including an energy confinement frame (ECF) using a transfer structure with a sacrificial layer. In these figure series described below, the “A” figures show diagrams illustrating top cross-sectional views of single crystal resonator devices according to various embodiments of the present invention. The “B” figures show diagrams illustrating lengthwise cross-sectional views of the same devices in the “A” figures. Similarly, the “C” figures show diagrams illustrating widthwise cross-sectional views of the same devices in the “A” figures. In some cases, certain features are omitted to highlight other features and the relationships between such features. Those of ordinary skill in the art will recognize variations, modifications, and alternatives to the examples shown in these figure series.

FIGS. 1A-C are diagrams illustrating various cross-sectional views of a single crystal acoustic resonator device and of operations for a transfer process using a sacrificial layer for single crystal acoustic resonator devices according to an example of the present invention. As shown, these figures illustrate the method step of forming a piezoelectric film 1620 overlying a growth substrate 1610. In some embodiments according to the present invention, the growth substrate 1610 can include silicon (S), silicon carbide (SiC), or other like materials. The single crystal piezoelectric film 1620 can be an epitaxial film including aluminum nitride (AlN), AlScN, gallium nitride (GaN), or other like materials. Additionally, this piezoelectric substrate can be subjected to a thickness trim.

In some embodiments according to the present invention, a first energy confinement layer 204 can be formed on the single crystal piezoelectric film 1620, as shown. The energy confinement layer 204 can be either a high-density material or a low-density material, such as W, Mo, AlN, ScAlN, SiO2, SiN, other materials may also be used. In some embodiments according to the present invention, the energy confinement layer 204 can be formed of SiO₂ and can have a thickness in a range between about 200 Angstroms and about 2000 Angstroms, and preferably have a thickness in a range between about 600 Angstroms and about 1000 Angstroms. In some embodiments according to the invention, a second energy confinement layer can be formed embedded in a second electrode as described herein. In still further embodiments according to the invention, the first or second energy confinement layer may be formed embedded in the respective electrode without forming the other energy confinement layer.

In some embodiments according to the present invention, the energy confinement layer 204 can be a metal having a density in a range between about 2.7 g/cm³ and about 20 g/cm³. In some embodiments according to the present invention, the energy confinement layer 204 can be a low-density material. In some embodiments according to the present invention, wherein the energy confinement layer 204 can be a low-density material having a density in a range between about 2.65 g/cm³ and about 3.26 g/cm³.

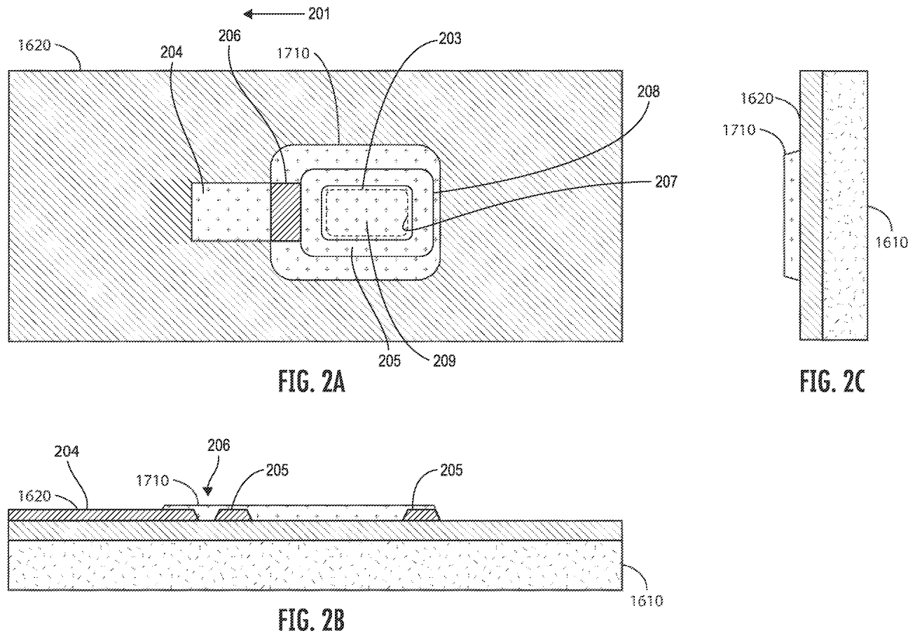

FIGS. 2A-2C are diagrams illustrating various cross-sectional views of a single crystal acoustic resonator device and of operations for a transfer process using a sacrificial layer for single crystal acoustic resonator devices according to an example of the present invention. As shown, these figures illustrate the operation of forming a first electrode 1710 overlying the surface region of the single crystal piezoelectric film 1620. In some embodiments according to the present invention, the first electrode 1710 can include any of the following materials including combinations thereof: Mo, Ru, W, Al, AlCu, TiW, Ir, etc. In some embodiments according to the present invention, the first electrode 1710 can be subjected to a dry etch with a slope. As an example, the slope can be about 60 degrees. In some embodiments according to the present invention, the first electrode 1710 is formed of a single layer of material.

As further shown in FIG. 2, the energy confinement layer 204 can be patterned to form an energy confinement frame 205 that is embedded within the first electrode 1710 wherein the outer side wall of the energy confinement frame 205 is aligned to the side walls of the first electrode 1710. Further, in some embodiments according to the present invention, a portion of the energy confinement layer 204 remains outside the first electrode 1710 and extends on the single crystal piezoelectric film 1620 in a direction 201 in which a second electrode contact area will be formed. Still further, in some embodiments according to the present invention, a recess 206 can be formed in the energy confinement layer 204 to separate the remaining energy confinement layer 204 from the energy confinement frame 205. Accordingly, as shown in FIG. 2A, in some embodiments according to the present invention, a recess 206 can be formed to remove a portion 206 of the energy confinement layer 204 so that the portion 206 forms an outer side wall of the energy confinement frame 205 that faces in the direction 201. Accordingly, in such embodiments according to the present invention, the inner and outer side walls of the energy confinement frame 205 can surround an active region 209 of the resonator device.

In other embodiments according to the present invention, the recess 206 is not formed in the energy confinement layer 204 so that the portion 206 of the energy confinement frame 205 remains and no outer side wall of the energy confinement frame 205 is formed proximate to the area where the second electrode contact area will be formed.

As further shown in FIG. 2, the energy confinement frame 205 includes the outer side wall 208 and an inner side wall 207 that extend on the surface of the single crystal piezoelectric film 1620 to define a perimeter 203 of the active region of the piezoelectric resonator device that is inside the inner side wall 207 of the energy confinement frame 205.

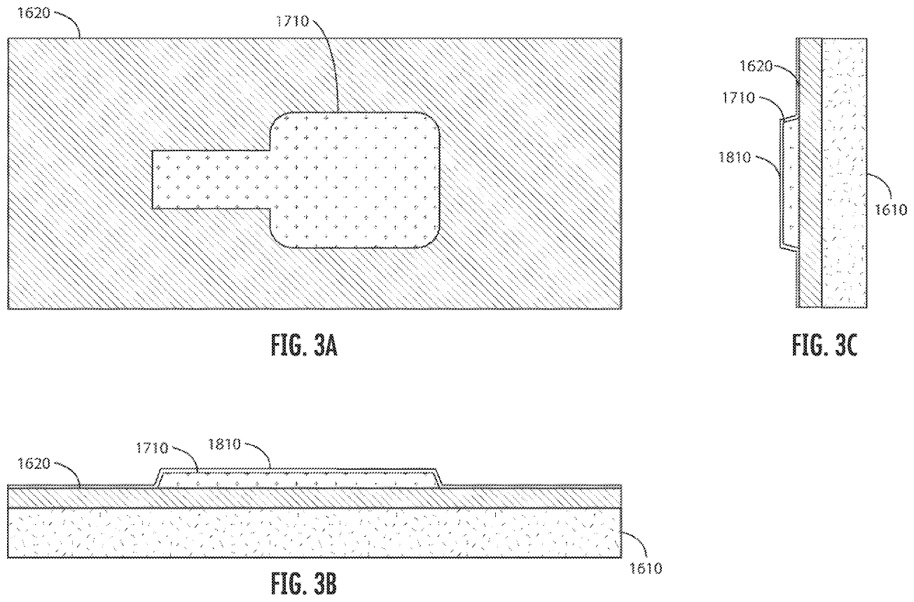

For the sake of clarity, some of the remaining figures (FIGS. 3-20) may not show the portion of the respective energy confinement layer 204 removed to form the recess for the particular embodiment. However, it will be understood that the recess may be formed in the respective energy confinement layer in any of the embodiments shown herein in some embodiments according to the invention. In some embodiments according to the invention, the structure shown in FIG. 2 can be present in each of the structures shown, for example, in FIGS. 3-20.

FIGS. 3A-3C are diagrams illustrating various cross-sectional views of a single crystal acoustic resonator device and of operations for a transfer process using a sacrificial layer for single crystal acoustic resonator devices according to an example of the present invention. As shown, these figures illustrate the method step of forming a first passivation layer 1810 overlying the first electrode 1710 and the single crystal piezoelectric film 1620. In some embodiments according to the present invention, the first passivation layer 1810 can include any of the following including combinations thereof: SiN, SiO2, AlN or Al₂O₃ or other like materials. In some embodiments according to the present invention, the first passivation layer 1810 can have a thickness ranging from about 50 nm to about 100 nm. In some embodiments according to the present invention, the first passivation layer 1810 can have a thickness ranging from about 100 Angstroms to about 1000 Angstroms.

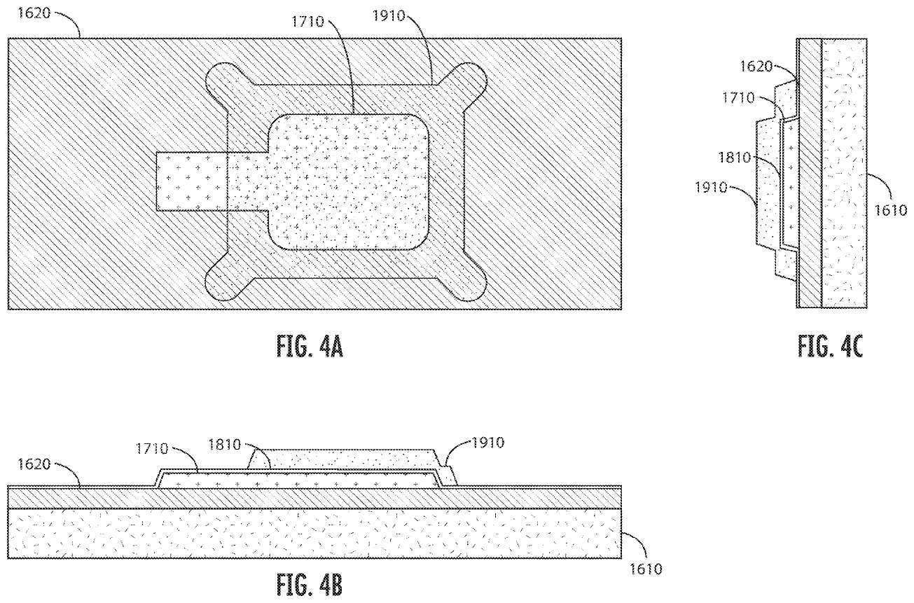

FIGS. 4A-4C are diagrams illustrating various cross-sectional views of a single crystal acoustic resonator device and of operations for a transfer process using a sacrificial layer for single crystal acoustic resonator devices according to an example of the present invention. As shown, these figures illustrate the method step of forming a sacrificial layer 1910 overlying a portion of the first electrode 1710 and a portion of the single crystal piezoelectric film 1620. In some embodiments according to the present invention, the sacrificial layer 1910 can include polycrystalline silicon (poly-Si), amorphous silicon (a-Si), polyimide, or other like materials. Further, phosphorous doped SiO.sub.2 (PSG) can be used as the sacrificial layer with different combinations of support layer (e.g., SiNx). In some embodiments according to the present invention, this sacrificial layer 1910 can be subjected to a dry etch with a slope and be deposited with a thickness of about 1 um. In some embodiments according to the present invention, this sacrificial layer 1910 can be deposited to have a thickness in a range between about 500 A and about 10000 A.

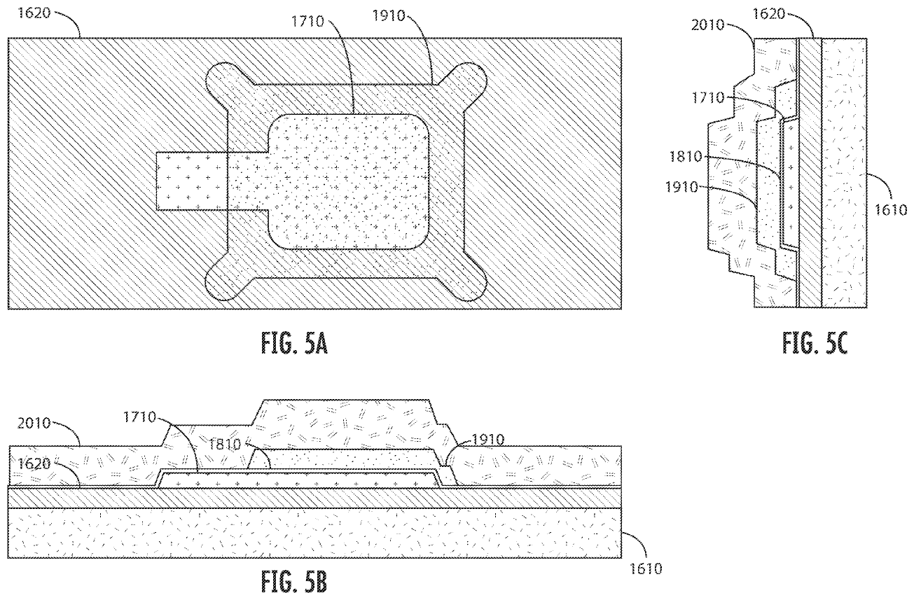

FIGS. 5A-5C are diagrams illustrating various cross-sectional views of a single crystal acoustic resonator device and of operations for a transfer process using a sacrificial layer for single crystal acoustic resonator devices according to an example of the present invention. As shown, these figures illustrate the method of forming a support layer 2010 overlying the sacrificial layer 1910, the first electrode 1710, and the single crystal piezoelectric film 1620. In some embodiments according to the present invention, the support layer 2010 can include silicon dioxide (SiO.sub.2), silicon nitride (SiN), or other like materials. In some embodiments according to the present invention, this support layer 2010 can be deposited with a thickness of about 2-4 um. As described above, other support layers (e.g., SiNx) can be used in the case of a PSG sacrificial layer.

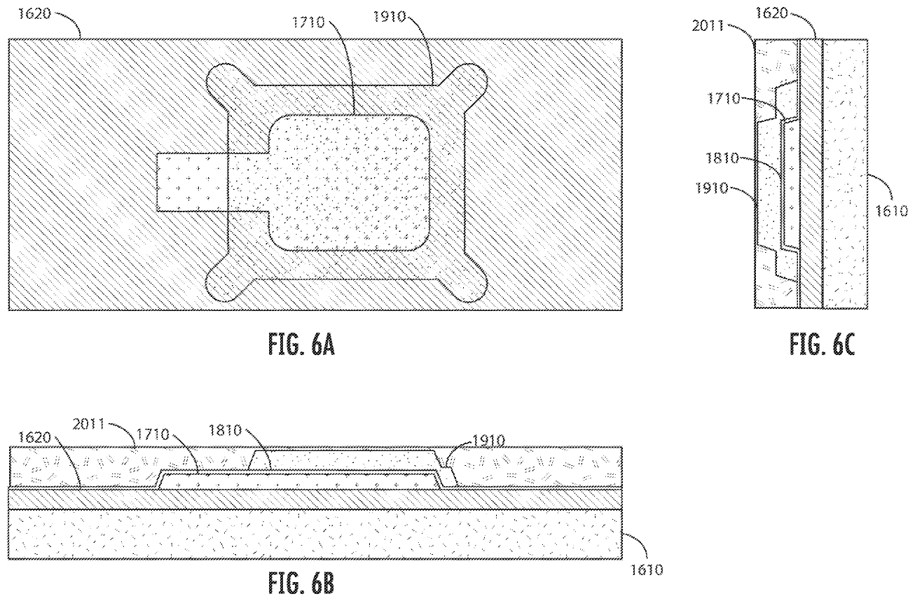

FIGS. 6A-6C are diagrams illustrating various cross-sectional views of a single crystal acoustic resonator device and of operations for a transfer process using a sacrificial layer for single crystal acoustic resonator devices according to an example of the present invention. As shown, these figures illustrate the method of polishing (e.g., CMP) the support layer 2010 to form a polished support layer 2011. In some embodiments according to the present invention, the polishing process can include a chemical-mechanical planarization process or the like.

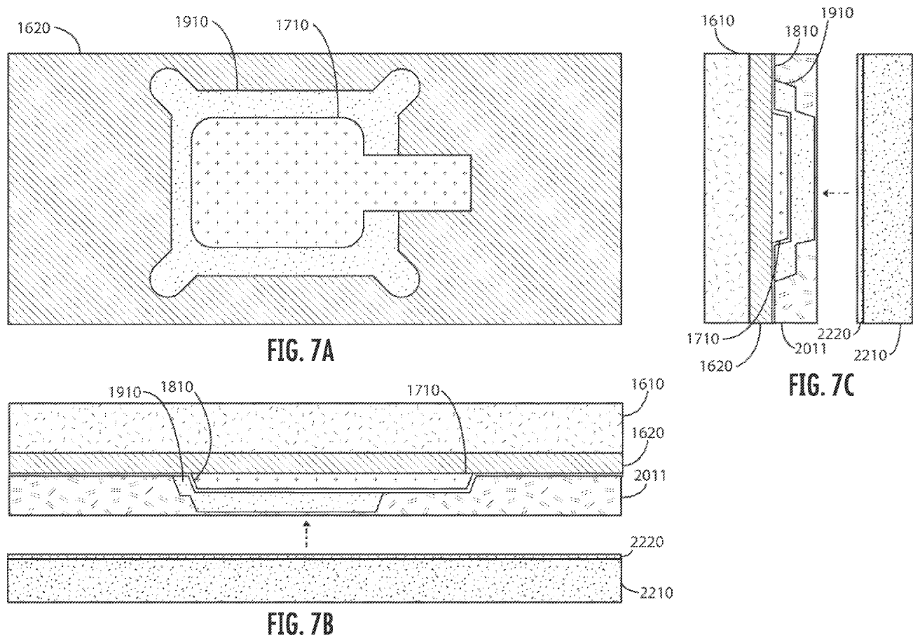

FIGS. 7A-7C are diagrams illustrating various cross-sectional views of a single crystal acoustic resonator device and of operations for a transfer process using a sacrificial layer for single crystal acoustic resonator devices according to an example of the present invention. As shown, these figures illustrate flipping the device and coupling overlying the support layer 2011 overlying a bond substrate 2210. In some embodiments according to the present invention, the bond substrate 2210 can include a bonding support layer 2220 (SiO.sub.2 or like material) overlying a substrate having silicon (Si), sapphire (Al.sub.2O.sub.3), silicon dioxide (SiO.sub.2), silicon carbide (SiC), AlN, or other like materials. In some embodiments according to the invention, the bonding support layer 2220 of the bond substrate 2210 is physically coupled to the polished support layer 2011. Further, the physical coupling process can include a room temperature bonding process following by a 300 degree Celsius annealing process.

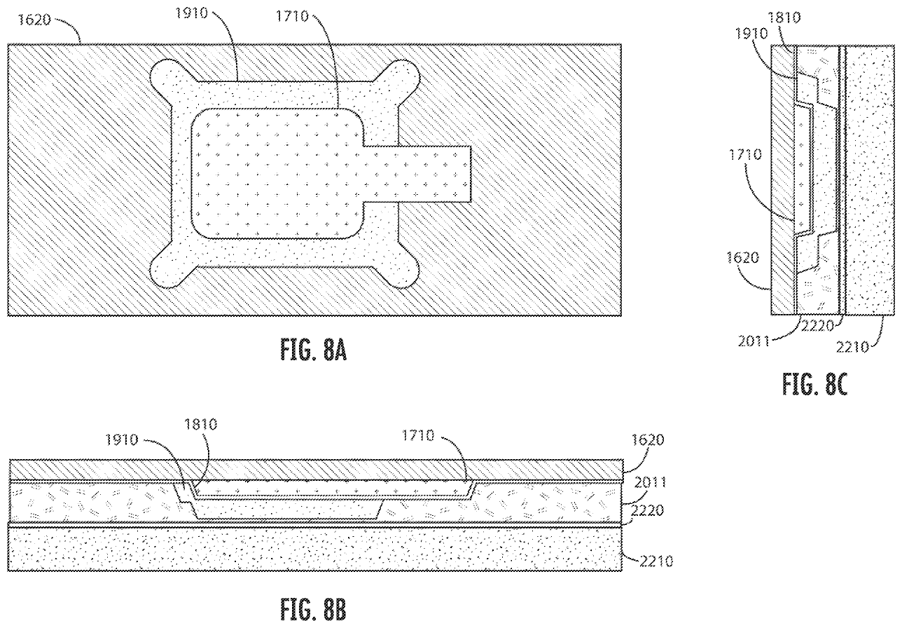

FIGS. 8A-8C are diagrams illustrating various cross-sectional views of a single crystal acoustic resonator device and of operations for a transfer process using a sacrificial layer for single crystal acoustic resonator devices according to an example of the present invention. As shown, these figures illustrate the method of removing the growth substrate 1610 or otherwise the transfer of the single crystal piezoelectric film 1620 to the bond substrate 2210. In some embodiments according to the present invention, the removal process can include a grinding process, a blanket etching process, a film transfer process, an ion implantation transfer process, a laser crack transfer process, or the like and combinations thereof.

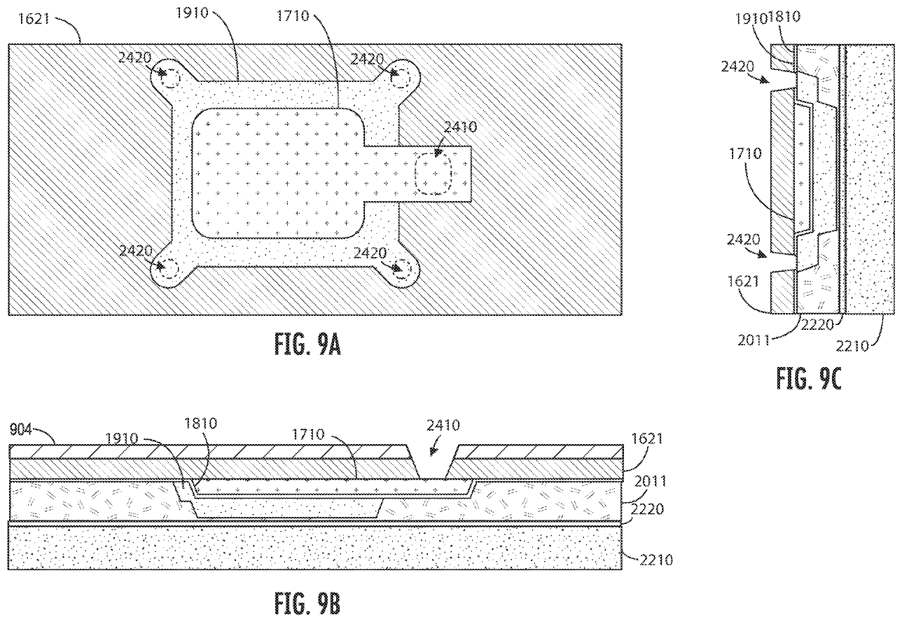

FIGS. 9A-9C are diagrams illustrating various cross-sectional views of a single crystal acoustic resonator device including an energy confinement frame and operations for a transfer process using a sacrificial layer for single crystal acoustic resonator devices according to an example of the present invention. As shown, these figures illustrate the method of forming an energy confinement layer 904 (in addition to the energy confinement layer 904 formed in some embodiments) on the single crystal piezoelectric film 1620. In some embodiments according to the invention, the energy confinement layer 904 can be a high-density material or a low-density material, such as W, Mo, AlN, ScAlN, SiO2, SiN, other materials may also be used. An electrode contact via 2410 is formed through the energy confinement layer 904 and through the single crystal piezoelectric film 1620 (becoming piezoelectric film 1621) to expose the first electrode 1710 and to form one or more release holes 2420 within the single crystal piezoelectric film 1620 and the first passivation layer 1810 overlying the sacrificial layer 1910. The via forming processes can include various types of etching processes.

In some embodiments according to the present invention, the energy confinement layer 904 can be a metal having a density in a range between about 2.7 g/cm³ and about 20 g/cm³. In some embodiments according to the present invention, the energy confinement layer 904 can be a low-density material. In some embodiments according to the present invention, wherein the energy confinement layer 904 can be a low-density material having a density in a range between about 2.65 g/cm³ and about 3.26 g/cm³.

It will be understood that although the energy confinement layer 904 is shown in FIG. 9B as being formed on the single crystal piezoelectric film 1621, in some embodiments according to the present invention, a second energy confinement layer may also be formed between the single crystal piezoelectric film 1621 and the first electrode 1710 so that energy confinement frames may be formed of both surfaces of the single crystal piezoelectric film 1621, as shown in FIGS. 1-2.

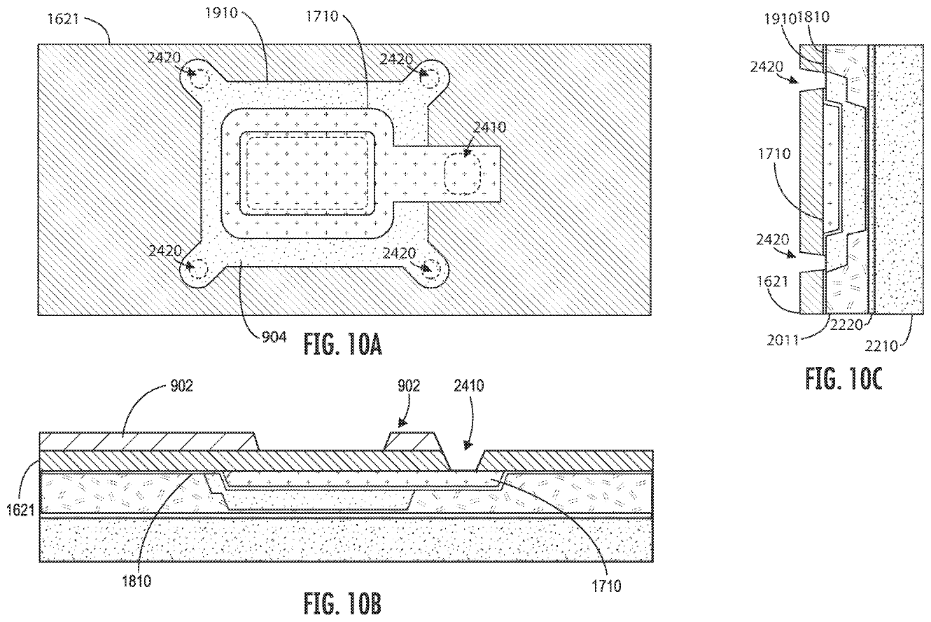

FIGS. 10-13 are diagrams illustrating various cross-sectional views of a single crystal acoustic resonator device including an energy confinement frame 905 and operations for forming an energy confinement frame 905 from the energy confinement layer 904 as part of a transfer process using a sacrificial layer for single crystal acoustic resonator devices according to an example of the present invention. According to FIG. 10, the energy confinement layer 904 is patterned to remove a section over a portion of the electrode 1710 that corresponds to the active portion of the single crystal acoustic resonator device being formed to form a patterned energy confinement layer 902 on the single crystal piezoelectric film 1621.

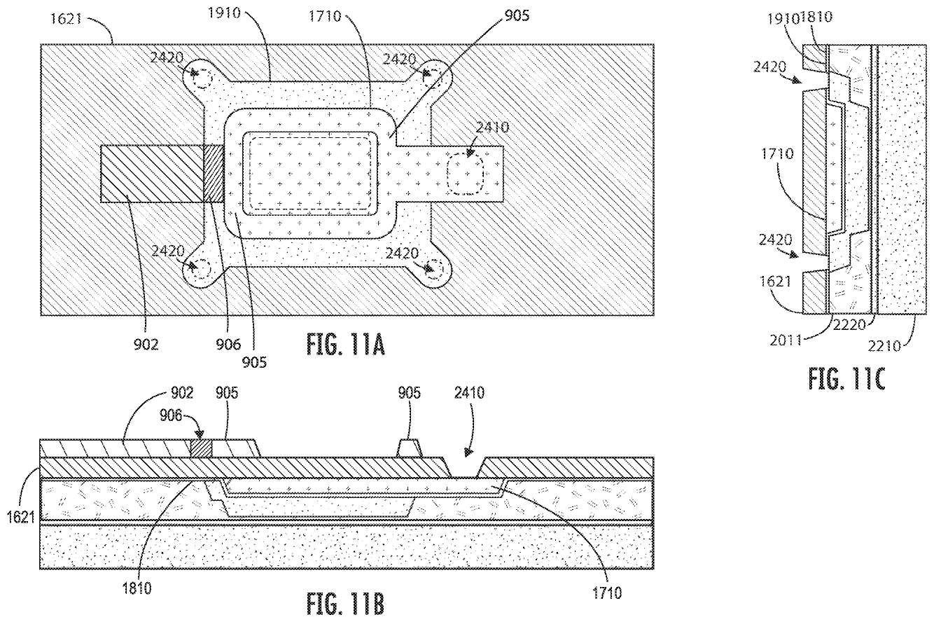

According to FIG. 11, the patterned energy confinement layer 902 can be further processed to remove the portion of the patterned energy confinement layer 902 that lies between the edge of the electrode contact via 2410 and the portion of the patterned energy confinement layer 902 that will remain to provide the outer perimeter of the energy confinement frame 905. As further shown in FIG. 11, a recess 906 may also be formed in the patterned energy confinement layer 902 outside the active portion of the single crystal acoustic resonator device as part of the same process described above in some embodiments. It will be further understood that the processes illustrated in FIGS. 10 and 11 may also be performed in a single operation in some embodiments.

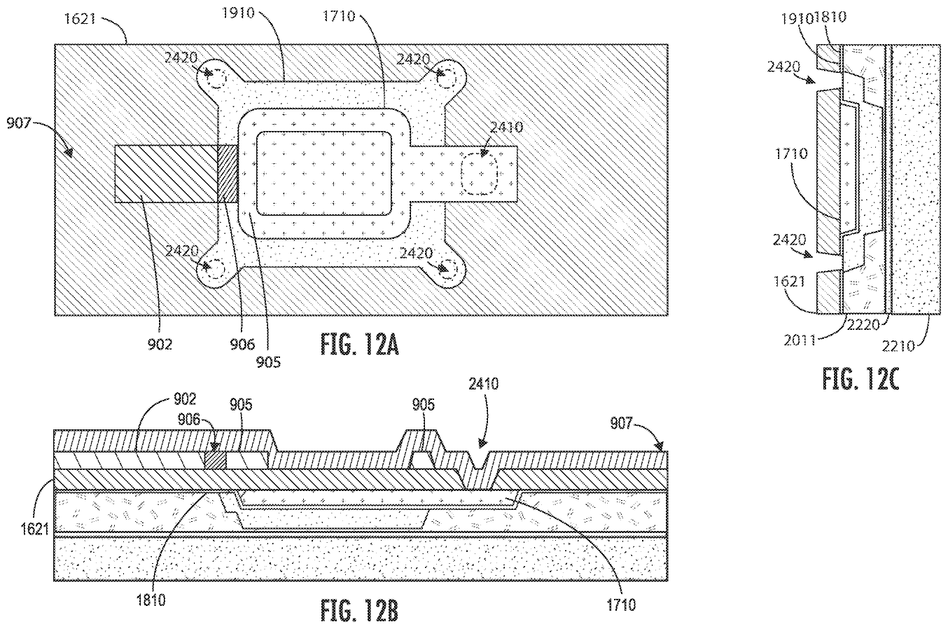

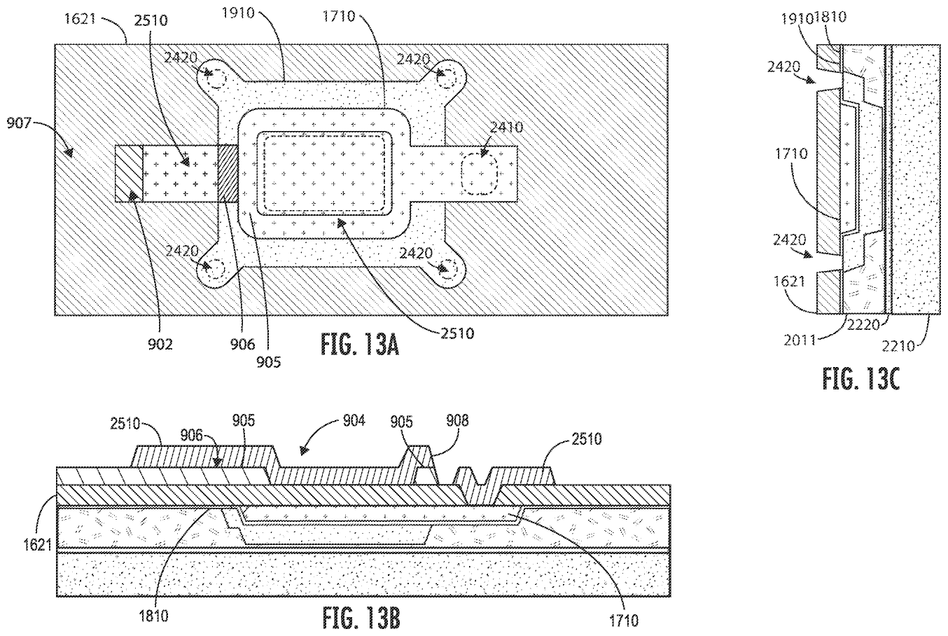

According to FIG. 12, a metal layer 907 is deposited over the single crystal piezoelectric film 1621, the energy confinement frame 905, and in the electrode contact via 2410. As shown in FIG. 13, the metal layer 907 can be processed to form the electrode 2510 so that the energy confinement frame 905 is embedded within the second electrode 2510 on the surface of the single crystal piezoelectric film 1621. In particular, in some embodiments according to the present invention, the portion of the metal layer 907 between the outer perimeter of the energy confinement frame 905 and the electrode contact via 2410 can be removed so that the outer edge of the energy confinement frame 905 is aligned with the side wall 908 of the second electrode 2510.

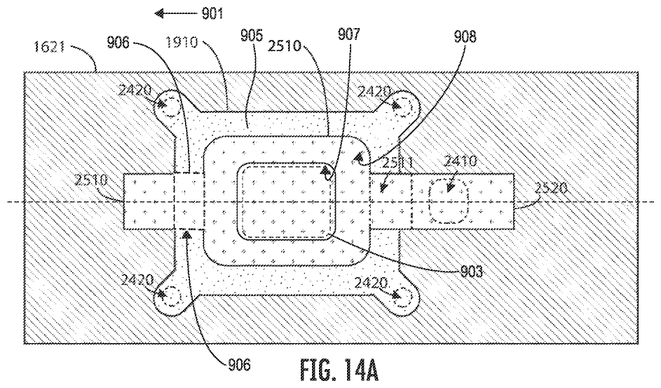

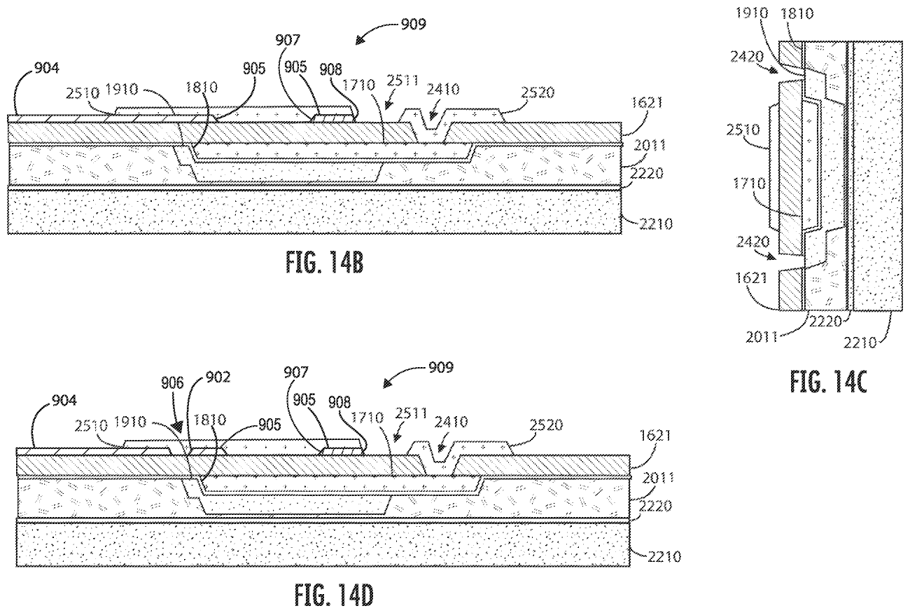

FIGS. 14A-14C are diagrams further illustrating the cross-sectional view of FIG. 13 including a single crystal acoustic resonator device and of operations for a transfer process using a sacrificial layer for single crystal acoustic resonator devices according to an example of the present invention. As shown, these figures illustrate the method of forming a second electrode 2510 overlying the single crystal piezoelectric film 1621 and having the energy confinement frame 905 formed therebetween so that the energy confinement frame 905 does not substantially protrude beyond the side wall 908 of the second electrode 2510. In some embodiments according to the present invention, the second electrode 2510 can include any of the following materials including combinations thereof: Mo, Ru, W, Al, AlCu, TiW, Ir, etc. The second electrode 2510 is then etched to form an electrode cavity 2511 (so that the energy confinement frame 905 is embedded within the second electrode 2510 and aligned to the side wall 908) from the second electrode to form a top metal 2520. Further, the top metal 2520 is physically coupled to the first electrode 1720 through electrode contact via 2410.

As further shown in FIG. 14, the energy confinement layer 904 can be patterned to form the energy confinement frame 905 that is embedded within the first electrode 1710 wherein the outer side wall 908 of the energy confinement frame 905 is aligned to the side walls of the first electrode 1810. Further, in some embodiments according to the present invention, a portion of the energy confinement layer 904 remains outside the first electrode 1710 and extends on the single crystal piezoelectric film 1621 in a direction 901 in which a second electrode contact area will be formed. Still further, in some embodiments according to the present invention, a recess 906 can be formed in the energy confinement layer 904 to separate the remaining energy confinement layer 904 from the energy confinement frame 905. Accordingly, as shown in FIG. 14A, in some embodiments according to the present invention, the recess 906 can be formed to remove a portion 902 of the energy confinement layer 904 so that the portion 902 forms an outer side wall of the energy confinement frame 905 that faces in the direction 901. Accordingly, in such embodiments according to the present invention, the inner and outer side walls of the energy confinement frame 905 can surround the active region 909.

In other embodiments according to the present invention, the recess 906 is not formed in the energy confinement layer 904 so that the portion 902 of the energy confinement layer 904 remains and no outer side wall of the energy confinement frame 905 is formed proximate to the area where the second electrode contact area will be formed.

As further shown in FIG. 14, the energy confinement frame 905 includes the outer side wall 908 and an inner side wall 907 that extend on the surface of the single crystal piezoelectric film 1621 to define a perimeter 903 of the active region of the piezoelectric.

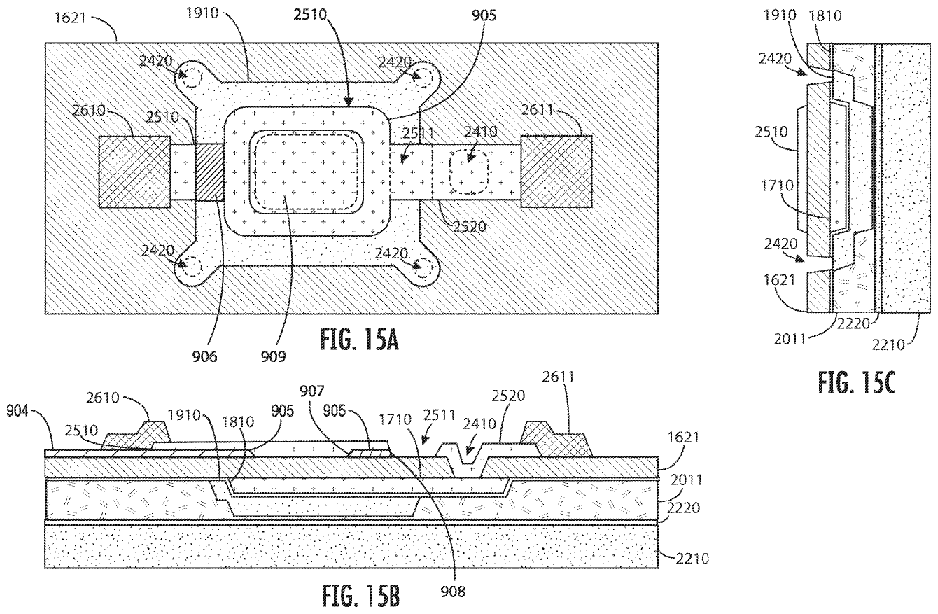

FIGS. 15A-15C are diagrams illustrating various cross-sectional views of a single crystal acoustic resonator device and of operations for a transfer process using a sacrificial layer for single crystal acoustic resonator devices according to an example of the present invention. As shown, these figures illustrate the method step of forming a first contact metal 2610 overlying a portion of the second electrode 2510, a portion of the energy confinement frame 905, and a portion of the single crystal piezoelectric film 1621, and forming a second contact metal 2611 overlying a portion of the top metal 2520 and a portion of the single crystal piezoelectric film 1621. In some embodiments according to the present invention, the first and second contact metals can include gold (Au), aluminum (Al), copper (Cu), nickel (Ni), aluminum bronze (AlCu), or related alloys of these materials or other like materials.

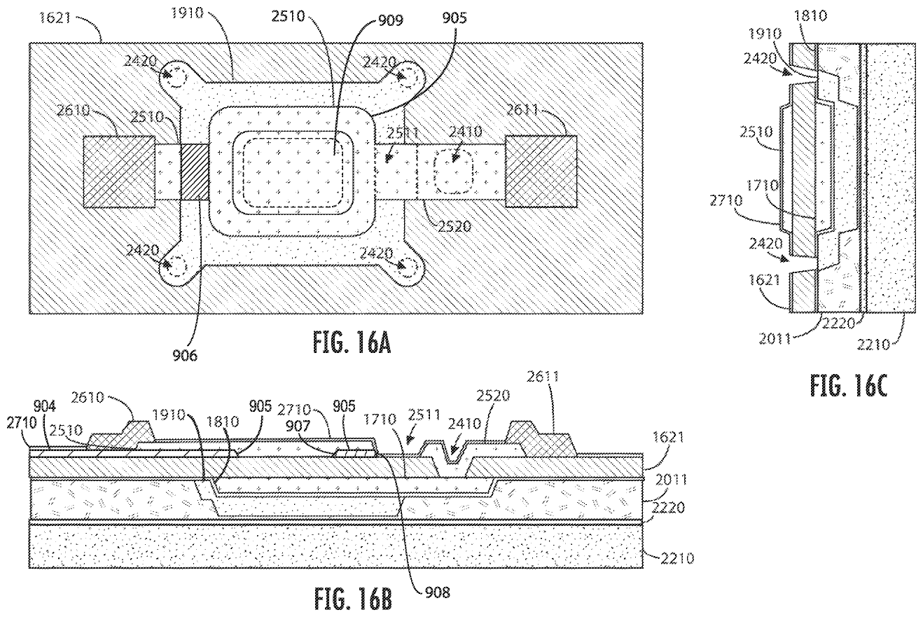

FIGS. 16A-16C are diagrams illustrating various cross-sectional views of a single crystal acoustic resonator device and of operations for a transfer process using a sacrificial layer for single crystal acoustic resonator devices according to an example of the present invention. As shown, these figures illustrate the method of forming a low-impedance acoustic layer 2710 overlying the second electrode 2510 (including over the active region 909), the sacrificial layer 1910, the top metal 2520, and the single crystal piezoelectric film 1621.

In some embodiments according to the present invention, the low-impedance acoustic layer 2710 can include any of the following including combinations thereof. SiN, SiO2, AlN or Al₂O₃ or other like materials. In some embodiments according to the present invention, the low-impedance acoustic layer 2710 can have a thickness ranging from about 50 nm to about 100 nm. In some embodiments according to the present invention, the low-impedance acoustic layer 2710 can have a thickness ranging from about 100 Angstroms to about 3000 Angstroms. It will be understood that the low-impedance acoustic layer 2710 can have the same thicknesses on the active region and on the outer region outside the active region, in some embodiments according to the invention.

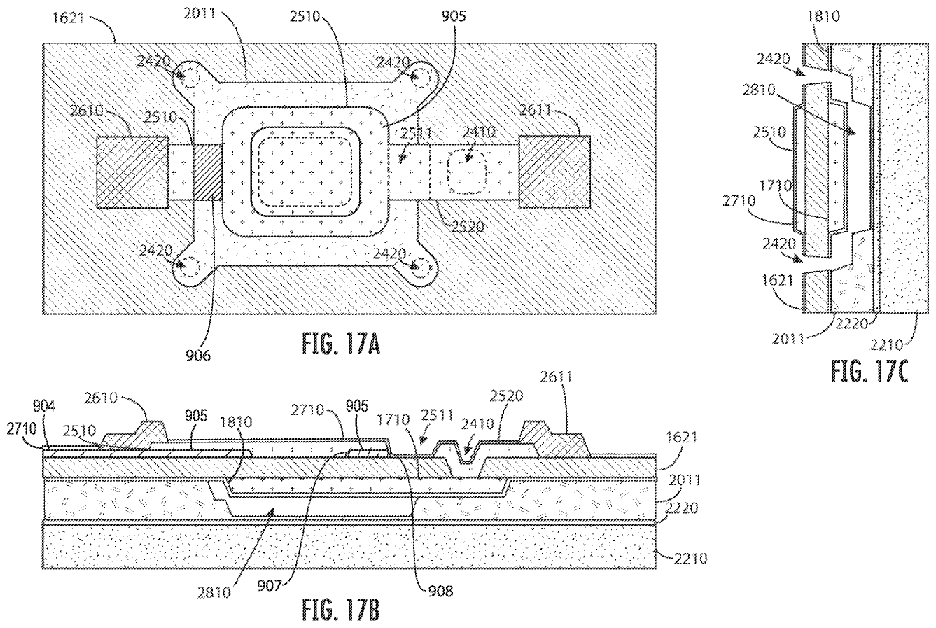

FIGS. 17A-17C are diagrams illustrating various cross-sectional views of a single crystal acoustic resonator device and of operations for a transfer process using a sacrificial layer for single crystal acoustic resonator devices according to an example of the present invention. As shown, these figures illustrate the method step of removing the sacrificial layer 1910 to form an air cavity 2810. In some embodiments according to the present invention, the removal process can include a poly-Si etch or an a-Si etch, or the like.

FIGS. 18A-18C are diagrams illustrating various cross-sectional views of a single crystal acoustic resonator device and of operations for a transfer process using a sacrificial layer for single crystal acoustic resonator devices according to another example of the present invention. As shown, these figures illustrate the method step of processing the second electrode 2510 and the top metal 2520 to form a processed second electrode 2912 and a processed top metal 2920. This step can follow the formation of second electrode 2510 and top metal 2520. In some embodiments according to the present invention, the processing of these two components includes depositing molybdenum (Mo), ruthenium (Ru), tungsten (W), or other like materials; and then etching (e.g., dry etch or the like) this material to form the processed second electrode 2912 with an electrode cavity and the processed top metal 2920. The processed top metal 2920 remains separated from the processed second electrode 2912 by the removal of portion 2911. In some embodiments according to the present invention, the processed second electrode 2910 is characterized by the addition of an energy confinement structure configured on the processed second electrode 2912 to increase Q.

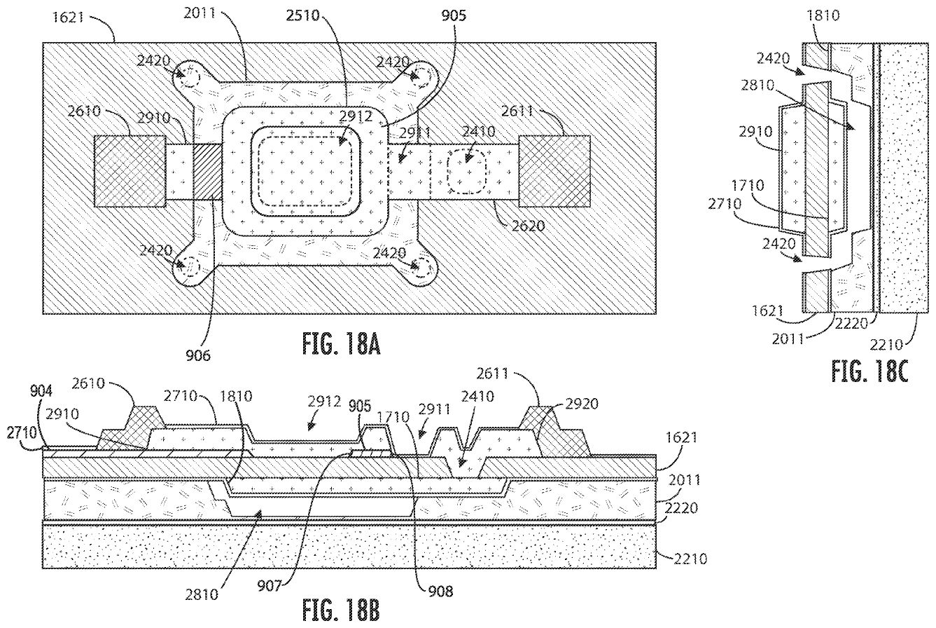

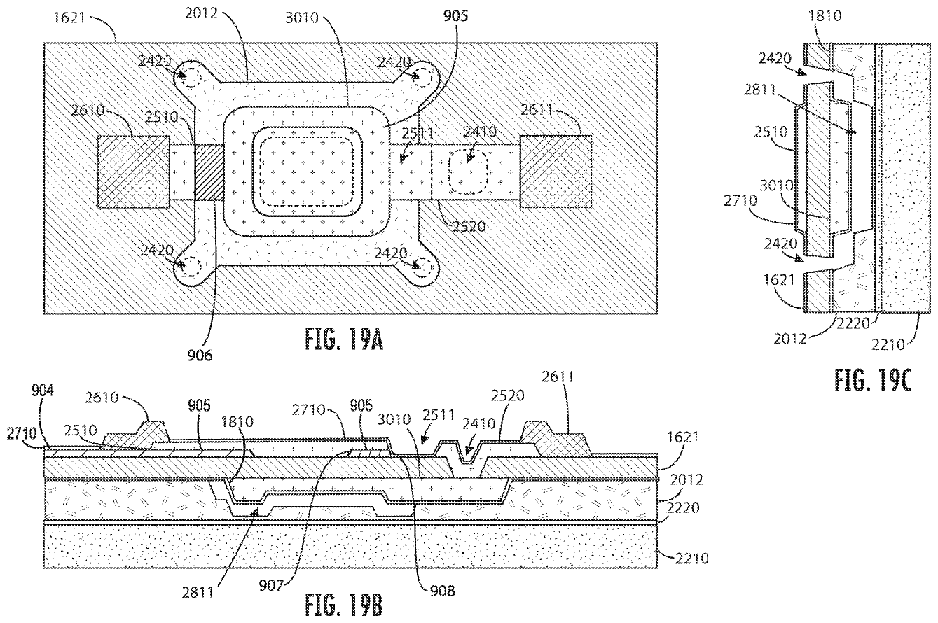

FIGS. 19A-19C are diagrams illustrating various cross-sectional views of a single crystal acoustic resonator device and of operations for a transfer process using a sacrificial layer for single crystal acoustic resonator devices according to another example of the present invention. As shown, these figures illustrate the method step of processing the first electrode 1710 to form a processed first electrode 3010. This step can follow the formation of first electrode 1710. In some embodiments according to the present invention, the processing of these two components includes depositing molybdenum (Mo), ruthenium (Ru), tungsten (W), or other like materials; and then etching (e.g., dry etch or the like) this material to form the processed first electrode 3010 with an electrode cavity 2811, similar to the processed second electrode 2910. Air cavity 2811 shows the change in cavity shape due to the processed first electrode 3010. In some embodiments according to the present invention, the processed first electrode 3010 is characterized by the addition of an energy confinement structure configured on the processed second electrode 3010 to increase Q.

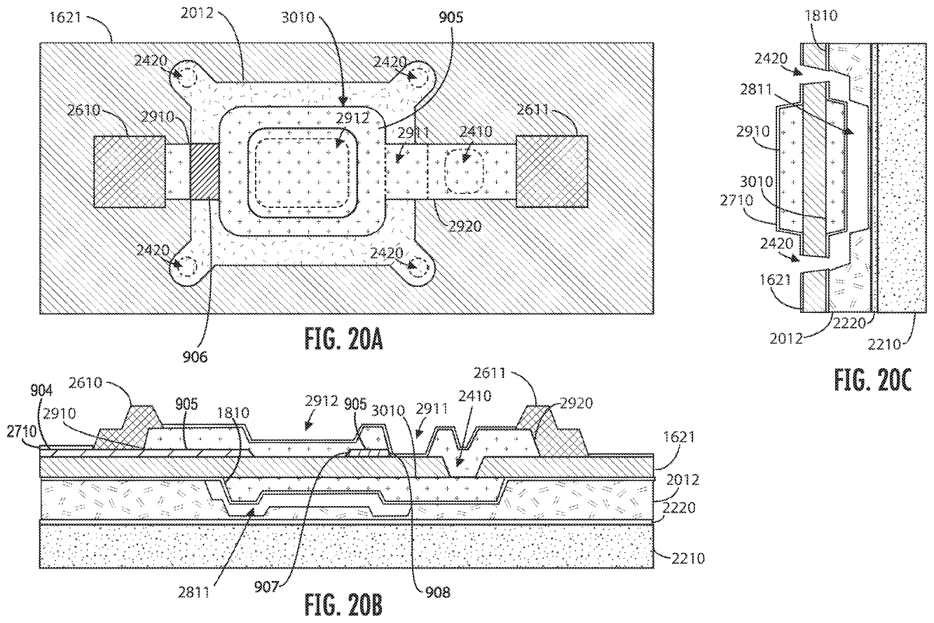

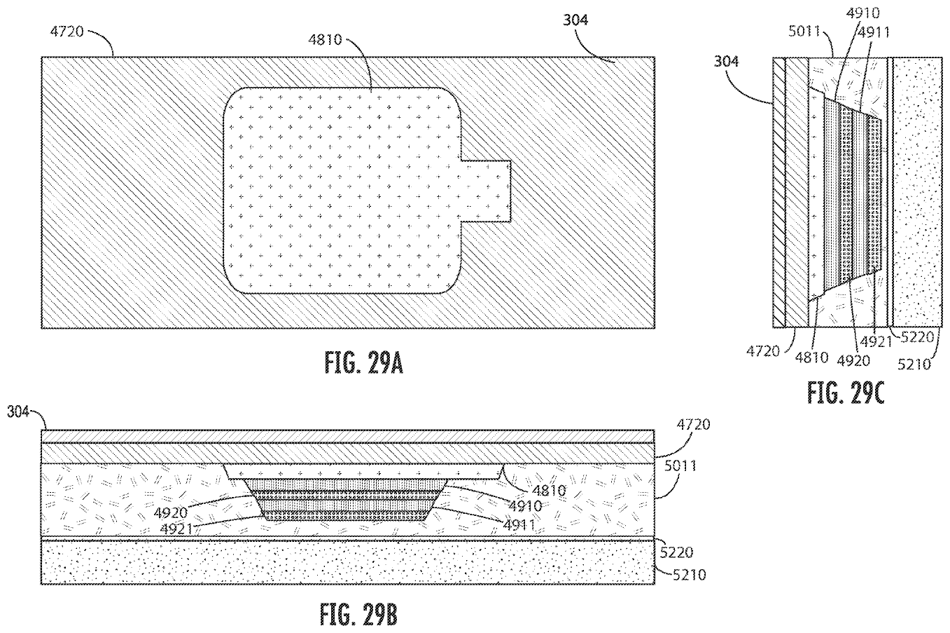

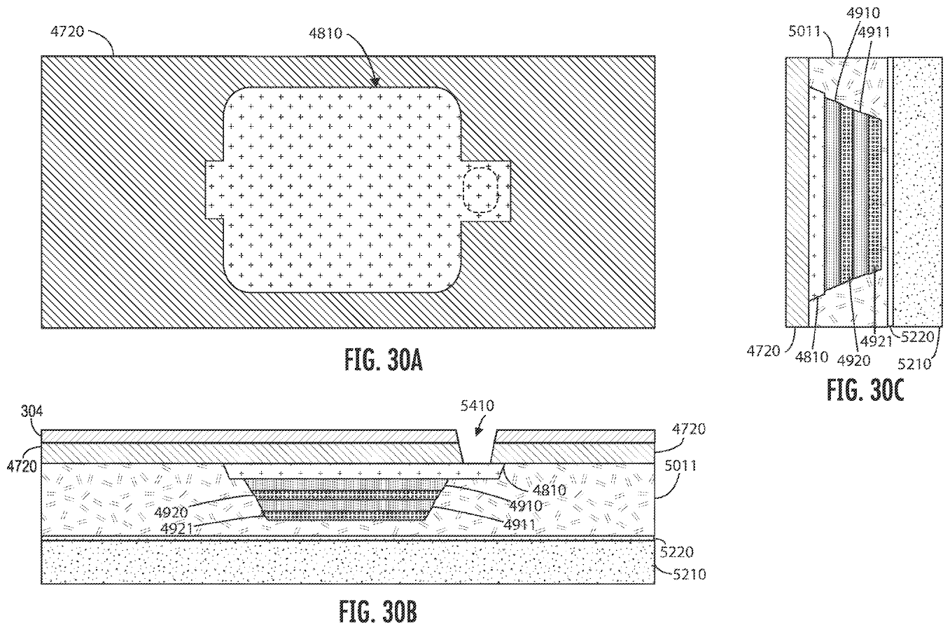

FIGS. 20A-20C are diagrams illustrating various cross-sectional views of a single crystal acoustic resonator device and of operations for a transfer process using a sacrificial layer for single crystal acoustic resonator devices according to another example of the present invention. As shown, these figures illustrate the method step of processing the first electrode 1710, to form a processed first electrode 3010, and the second electrode 2510/top metal 2520 to form a processed second electrode 2910/processed top metal 2920. These steps can follow the formation of each respective electrode, as described for FIGS. 29A-29C and 30A-30C. Those of ordinary skill in the art will recognize other variations, modifications, and alternatives.

FIG. 21 is a cross-sectional view of a piezoelectric resonator device including an energy confinement frame in some embodiment according to the present invention. As shown in FIG. 21, the energy confinement frame 905 is located on the single crystal piezoelectric film 1621 beneath the second electrode 2510. Furthermore, in some embodiments according to the present invention, the energy confinement frame 905 defines the perimeter within which the active region of the piezoelectric resonator device is located whereas the outer region, beyond the energy confinement frame 905, includes the area outside the active region of the piezoelectric resonator device as shown. In some embodiments according to the present invention, the energy confinement layer 904 can be formed of SiO₂ and can have a thickness in a range between about 200 Angstroms and about 2000 Angstroms, and preferably have a thickness in a range between about 600 Angstroms and about 1000 Angstroms. In some embodiments according to the present invention, the energy confinement frame 905 can have substantially the same thickness as the energy confinement layer 904 and may vary due to, for example, the effects of processing the layers and structures as described herein.

In some embodiments according to the present invention, the passivation layer 2710 can have a conformal profile on the second electrode 2510 to extend over the active region and over the energy confinement frame 905 onto the side wall 908 of the second electrode 2510 and onto the directly adjacent portion of the single crystal piezoelectric film 1621 in the outer region. Accordingly, the portion of the passivation layer 2710 over the active region can have substantially the same thickness as the portion of the passivation layer 2710 on the directly adjacent portion of the single crystal piezoelectric film 1621. In some embodiments according to the present invention, the passivation layer 2710 can be formed of SiN to have a thickness in a range between about 100 Angstroms and about 3000 Angstroms.

As further shown, in some embodiments according to the present invention, the energy confinement layer 904 can extend on the single crystal piezoelectric film 1621 beyond the energy confinement frame 905 into the outer region on the side of the piezoelectric resonator device that includes the contact area ohmically coupled to the second electrode 2510. In contrast, in some embodiments according to the present invention, the energy confinement layer 904 on the side of the piezoelectric resonator device that includes the contact area ohmically coupled to the first electrode 1710 is confined to beneath the second electrode 2510 and does not extend beyond the side wall 908 as the energy confinement layer 904 on the directly adjacent portion of the single crystal piezoelectric film 1621, has been removed prior to formation of the passivation layer 2710.

In some embodiments according to the present invention, the portion of the energy confinement frame 905 on the side of the piezoelectric resonator device that includes the contact area ohmically coupled to the first electrode 1710 has a cross-sectional width in a range between about 0.1 micrometers and about 10 micrometers. In some embodiments according to the present invention, the recess 906 can be formed in the energy confinement layer 904 so that the resulting portion 906 of the energy confinement frame 905 on the side of the piezoelectric resonator device that includes the contact area ohmically coupled to the second electrode 2510 has a cross-section width in a range between about 0.1 micrometers and about 10 micrometers.

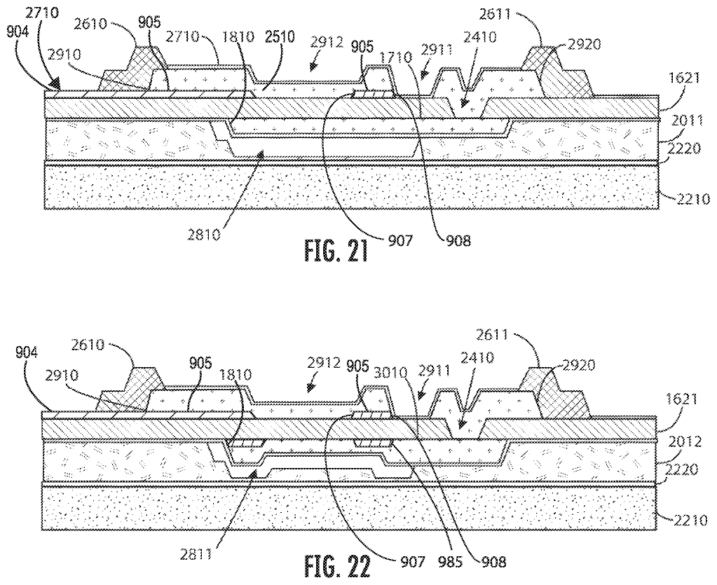

FIG. 22 is a cross-sectional view of a piezoelectric resonator device including first and second energy confinement frames 905 respectively located on the lower surface and the upper surface of the single crystal piezoelectric film 1621 in some embodiment according to the present invention. As shown in FIG. 22, the energy confinement frames 905 are located between the upper surface of the single crystal piezoelectric film 1621 and the second electrode 2910 and located between the lower surface of the single crystal piezoelectric film 1621 and the first electrode 3010. In some embodiments according to the invention, the first and second energy confinement frames 905 are aligned with one another to define the active region of the piezoelectric resonator device. In some embodiments according to the invention, the first and second energy confinement layers 904 can include a recess 906 to define the respective first and second energy confinement frame 905. Accordingly, in some embodiments according to the invention, either or both of the first and second energy confinement frames 905 may be formed using the recess 906. Still further, in some embodiments according to the invention, the first and second energy confinement frames 905 of FIG. 22 can have substantially the same thicknesses and be formed of the same materials as described herein.

It will be understood that that, in some embodiments according to the invention, the surface of the first processed electrode 3010 can be planar.

FIGS. 23A-2C through FIGS. 39A-39C illustrate a method of fabrication for an acoustic resonator device including an energy confinement frame (ECF) using a transfer structure with a multilayer mirror structure. In these figure series described below, the “A” figures show diagrams illustrating top cross-sectional views of single crystal resonator devices according to various embodiments of the present invention. The “B” figures show diagrams illustrating lengthwise cross-sectional views of the same devices in the “A” figures. Similarly, the “C” figures show diagrams illustrating widthwise cross-sectional views of the same devices in the “A” figures. In some cases, certain features are omitted to highlight other features and the relationships between such features. Those of ordinary skill in the art will recognize variations, modifications, and alternatives to the examples shown in these figure series.

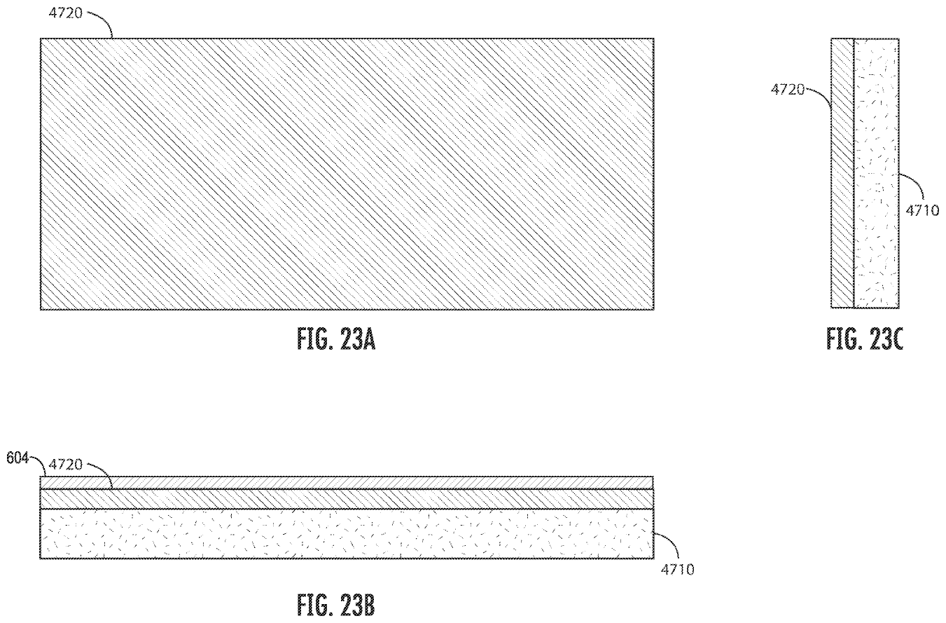

FIGS. 23A-2C are diagrams illustrating various cross-sectional views of a single crystal acoustic resonator device and of operations for a transfer process with a multilayer mirror for single crystal acoustic resonator devices according to an example of the present invention. As shown, these figures illustrate the method of forming a piezoelectric film 4720 overlying a growth substrate 4710. In some embodiments according to the present invention, the growth substrate 4710 can include silicon (S), silicon carbide (SiC), or other like materials. The single crystal piezoelectric film 4720 can be an epitaxial film including aluminum nitride (AlN), AlScN, gallium nitride (GaN), or other like materials. Additionally, this piezoelectric substrate can be subjected to a thickness trim.

In some embodiments according to the present invention, an energy confinement layer 604 can be formed on the single crystal piezoelectric film 4720, as shown. The energy confinement layer 604 can be either or both a high-density material or a low-density material, such as W, Mo, AlN, ScAlN, SiO2, SiN, other materials may also be used. In some embodiments according to the present invention, the energy confinement layer 604 can be formed of SiO₂ and can have a thickness in a range between about 200 Angstroms and about 2000 Angstroms, and preferably a thickness in a range between about 600 Angstroms to 1000 Angstroms.

In some embodiments according to the present invention, the energy confinement layer 604 can be a metal having a density in a range between about 2.7 g/cm³ and about 20 g/cm³. In some embodiments according to the present invention, the energy confinement layer 604 can be a low-density material. In some embodiments according to the present invention, wherein the energy confinement layer 604 can be a low-density material having a density in a range between about 2.65 g/cm³ and about 3.26 g/cm³.

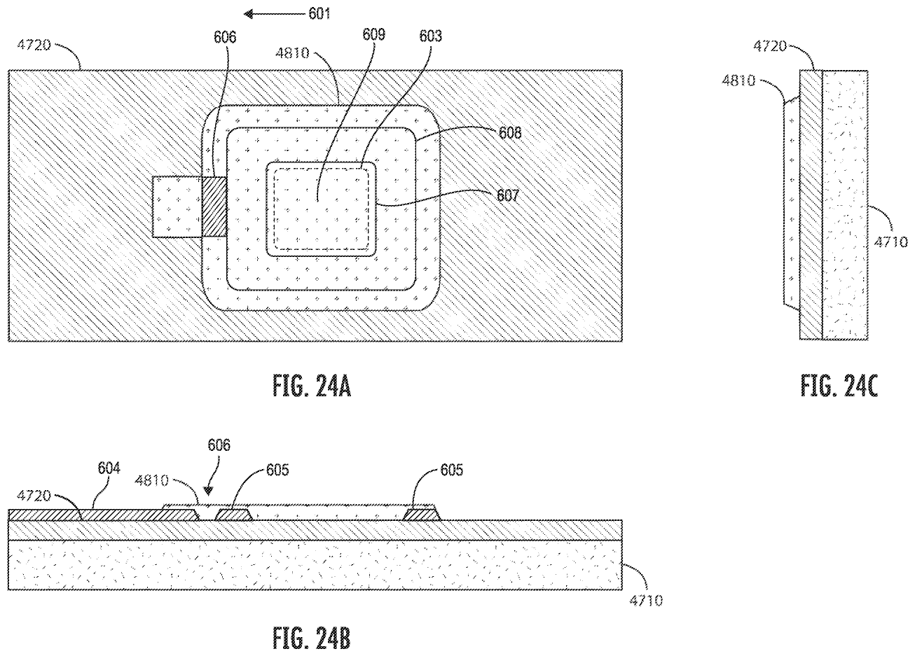

FIGS. 24A-24C are diagrams illustrating various cross-sectional views of a single crystal acoustic resonator device and of operations for a transfer process with a multilayer mirror for single crystal acoustic resonator devices according to an example of the present invention. As shown, these figures illustrate the method step of forming a first electrode 4810 overlying the surface region of the single crystal piezoelectric film 4720. In some embodiments according to the present invention, the first electrode 4810 can include molybdenum (Mo), ruthenium (Ru), tungsten (W), or other like materials. In some embodiments according to the present invention, the first electrode 4810 can be subjected to a dry etch with a slope. As an example, the slope can be about 60 degrees. In some embodiments according to the present invention, the first electrode 4810 is formed of a single layer of material.

As further shown in FIG. 24, the energy confinement layer 604 can be patterned to form an energy confinement frame 605 that is embedded within the first electrode 4810 wherein the outer side wall 608 of the energy confinement frame 605 is aligned to the side walls of the first electrode 4810. Further, in some embodiments according to the present invention, a portion of the energy confinement layer 604 remains outside the first electrode 4810 and extends on the single crystal piezoelectric film 4720 in a direction 601 in which a second electrode contact area will be formed. Still further, in some embodiments according to the present invention, a recess 606 can be formed in the energy confinement layer 604 to separate the remaining energy confinement layer 604 from the energy confinement frame 605. Accordingly, as shown in FIG. 24A, in some embodiments according to the present invention, the recess 606 can be formed to remove a portion of the energy confinement layer 604 to form an outer side wall 608 of the energy confinement frame 605 that faces in the direction 601. Accordingly, in such embodiments according to the present invention, the inner and outer side walls of the energy confinement frame 605 can surround the active region 609.

In other embodiments according to the present invention, the recess 606 is not formed in the energy confinement layer 604 so that the portion of the energy confinement frame 605 remains and no outer side wall of the energy confinement frame 605 is formed proximate to the area where the second electrode contact area will be formed.

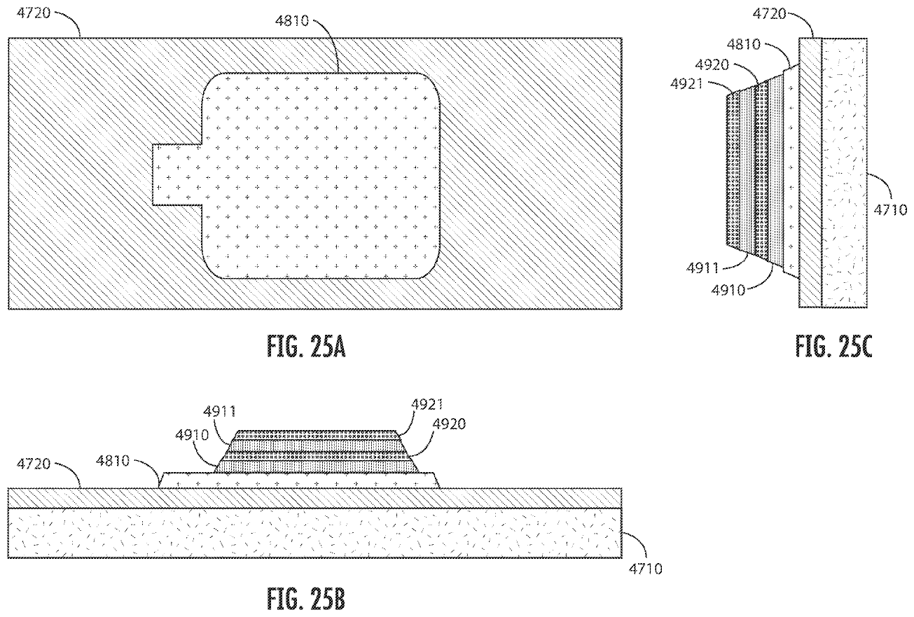

As further shown in FIG. 24, the energy confinement frame 605 includes the outer side wall 608 and an inner side wall 607 that extend on the surface of the single crystal piezoelectric film 4720 to define a perimeter 603 of the active region of the piezoelectric resonator device that is inside the inner side wall 607 of the energy confinement frame 605. In some embodiments according to the invention, the energy confinement frame 605 shown in FIG. 24 can be present in the structures in FIGS. 25-36.

FIGS. 25A-25C are diagrams illustrating various cross-sectional views of a single crystal acoustic resonator device and of operations for a transfer process with a multilayer mirror for single crystal acoustic resonator devices according to an example of the present invention. As shown, these figures illustrate the method step of forming a multilayer mirror or reflector structure. In some embodiments according to the present invention, the multilayer mirror includes at least one pair of layers with a low impedance layer 4910 and a high impedance layer 4920. In FIGS. 25A-25C, two pairs of low/high impedance layers are shown (low: 4910 and 4911; high: 4920 and 4921). In some embodiments according to the present invention, the mirror/reflector area can be larger than the resonator area and can encompass the resonator area. In a specific embodiment, each layer thickness is about ¼ of the wavelength of an acoustic wave at a targeting frequency. The layers can be deposited in sequence and be etched afterwards, or each layer can be deposited and etched individually. In another example, the first electrode 4810 can be patterned after the mirror structure is patterned.

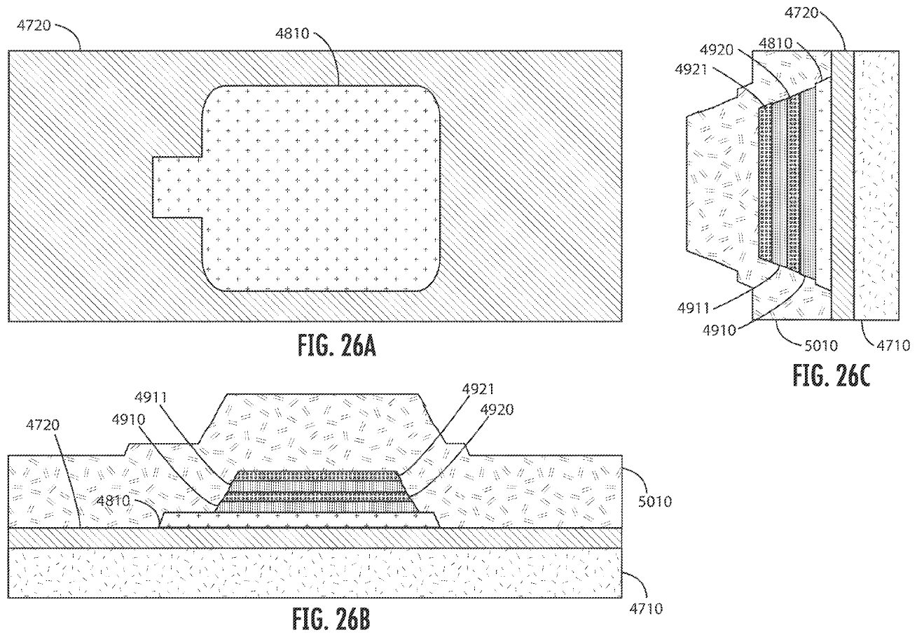

FIGS. 26A-26C are diagrams illustrating various cross-sectional views of a single crystal acoustic resonator device and of operations for a transfer process with a multilayer mirror for single crystal acoustic resonator devices according to an example of the present invention. As shown, these figures illustrate the method step of forming a support layer 5010 overlying the mirror structure (layers 4910, 4911, 4920, and 4921), the first electrode 4810, and the single crystal piezoelectric film 4720. In some embodiments according to the present invention, the support layer 5010 can include silicon dioxide (SiO.sub.2), silicon nitride (SiN), or other like materials. In some embodiments according to the present invention, this support layer 5010 can be deposited with a thickness of about 2-3 um. As described above, other support layers (e.g., SiNx) can be used.

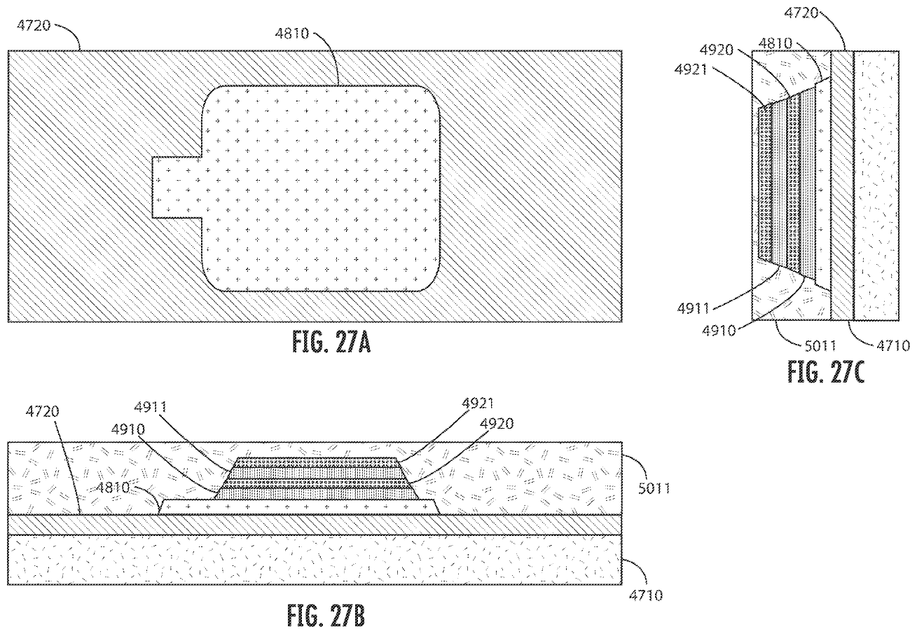

FIGS. 27A-27C are diagrams illustrating various cross-sectional views of a single crystal acoustic resonator device and of operations for a transfer process with a multilayer mirror for single crystal acoustic resonator devices according to an example of the present invention. As shown, these figures illustrate the method step of polishing the support layer 5010 to form a polished support layer 5011. In some embodiments according to the present invention, the polishing process can include a chemical-mechanical planarization process or the like.

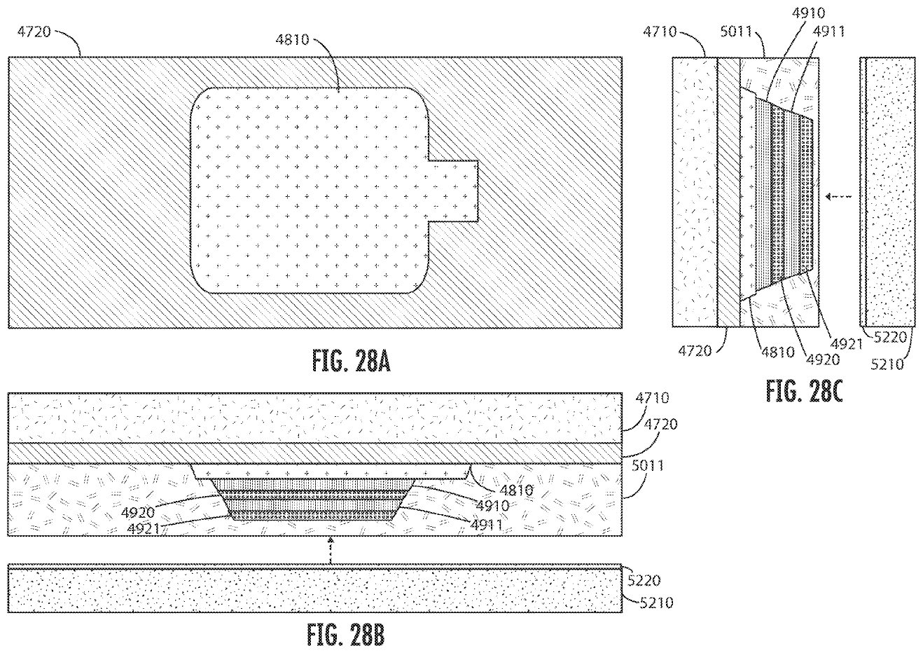

FIGS. 28A-28C (52A-52C) are diagrams illustrating various cross-sectional views of a single crystal acoustic resonator device and of operations for a transfer process with a multilayer mirror for single crystal acoustic resonator devices according to an example of the present invention. As shown, these figures illustrate flipping the device and physically coupling overlying the support layer 5011 overlying a bond substrate 5210. In some embodiments according to the present invention, the bond substrate 5210 can include a bonding support layer 5220 (SiO.sub.2 or like material) overlying a substrate having silicon (Si), sapphire (Al.sub.2O.sub.3), silicon dioxide (SiO.sub.2), silicon carbide (SiC), or other like materials. In a specific embodiment, the bonding support layer 5220 of the bond substrate 5210 is physically coupled to the polished support layer 5011. Further, the physical coupling process can include a room temperature bonding process following by a 300 degree Celsius annealing process.

FIGS. 29A-29C are diagrams illustrating various cross-sectional views of a single crystal acoustic resonator device and of operations for a transfer process with a multilayer mirror for single crystal acoustic resonator devices according to an example of the present invention. As shown, these figures illustrate the method step of removing the growth substrate 4710 or otherwise the transfer of the single crystal piezoelectric film 4720. In some embodiments according to the present invention, the removal process can include a grinding process, a blanket etching process, a film transfer process, an ion implantation transfer process, a laser crack transfer process, or the like and combinations thereof.

In some embodiments according to the present invention, an energy confinement layer 304 can be formed on the single crystal piezoelectric film 4720, as shown. The energy confinement layer 304 can be a high-density material or a low-density material, such as W, Mo, AlN, ScAlN, SiO2, SiN, other materials may also be used. In some embodiments according to the present invention, the energy confinement layer 304 can be formed of SiO₂ and can have a thickness in a range between about 200 Angstroms and about 2000 Angstroms, and preferably have a thickness in a range between about 600 Angstroms and about 1000 Angstroms.

In some embodiments according to the present invention, the energy confinement layer 304 can be a metal having a density in a range between about 2.7 g/cm³ and about 20 g/cm³. In some embodiments according to the present invention, the energy confinement layer 304 can be a low-density material. In some embodiments according to the present invention, the energy confinement layer 304 can be a low-density material having a density in a range between about 2.65 g/cm³ and about 3.26 g/cm³.

FIGS. 30A-30C are diagrams illustrating various cross-sectional views of a single crystal acoustic resonator device and of operations for a transfer process with a multilayer mirror for single crystal acoustic resonator devices according to an example of the present invention.

It will be understood that although the energy confinement layer 304 is shown in FIG. 30B as being formed on the single crystal piezoelectric film 4720, in some embodiments according to the present invention, a second energy confinement layer may also be formed between the single crystal piezoelectric film 4720 and the first electrode 4810 so that energy confinement frames may be formed of both surfaces of the single crystal piezoelectric film 4720, as shown in FIGS. 23-24 and FIG. 41. An electrode contact via 5410 is formed through the energy confinement layer 304 and through the single crystal piezoelectric film 4720 to expose the first electrode 4810. The via forming processes can include various types of etching processes.

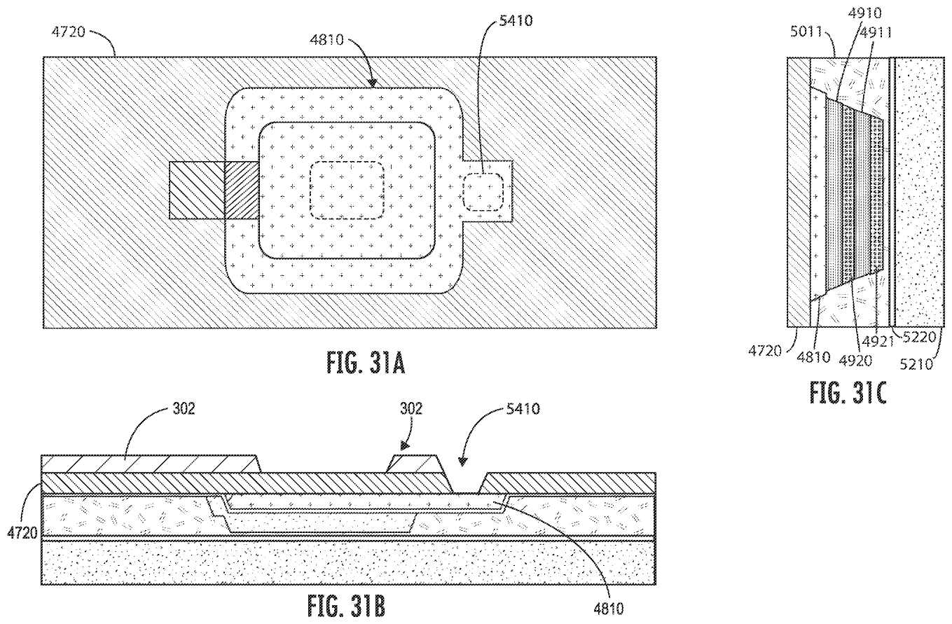

FIGS. 31-34 are diagrams illustrating various cross-sectional views of a single crystal acoustic resonator device with energy confinement frames and operations for forming an energy confinement frame 305 from the energy confinement layer 304 as part of a transfer process for single crystal acoustic resonator devices according to an example of the present invention. According to FIG. 31, the energy confinement layer 304 is patterned to remove a section over a portion of the first electrode 4810 that corresponds to the active portion of the single crystal acoustic resonator device being formed to provide a patterned energy confinement layer 302 on the single crystal piezoelectric film 4720.

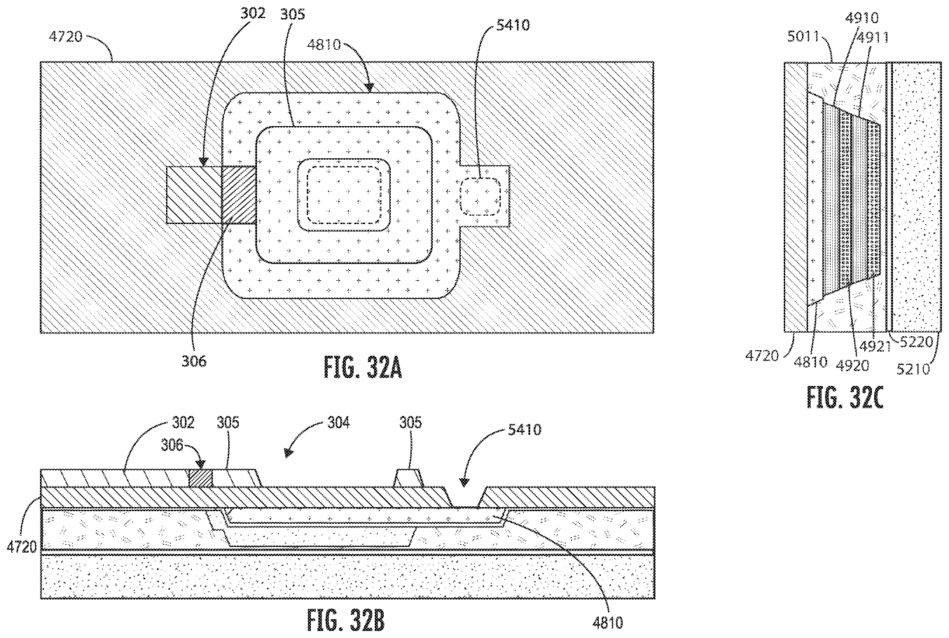

According to FIG. 31, the patterned energy confinement layer 302 can be further processed to remove the portion of the patterned energy confinement layer 302 that lies between the edge of the electrode contact via 5410 and the portion of the patterned energy confinement layer 302 that will remain to provide the outer perimeter of the energy confinement frame 305. As further shown in FIG. 32, a recess 306 may also be formed in the patterned energy confinement layer 302 outside the active portion of the single crystal acoustic resonator device as part of the same process described above in some embodiments. It will be further understood that the processes illustrated in FIGS. 31 and 32 may also be performed in a single operation in some embodiments.

According to FIG. 33, a metal layer 307 is deposited over the single crystal piezoelectric film 4720, the energy confinement frame 305, and in the electrode contact via 5410. As shown in FIG. 34, the metal layer 307 can be processed to form the second electrode 5510 so that the energy confinement frame 305 is embedded within the second electrode 5510 on the surface of the single crystal piezoelectric film 4720. In particular, in some embodiments according to the present invention, the portion of the metal layer 307 between the outer perimeter of the energy confinement frame 305 and the electrode contact via 5410 can be removed so that the outer edge of the energy confinement frame 305 is aligned with the side wall 308 of the second electrode 5510.

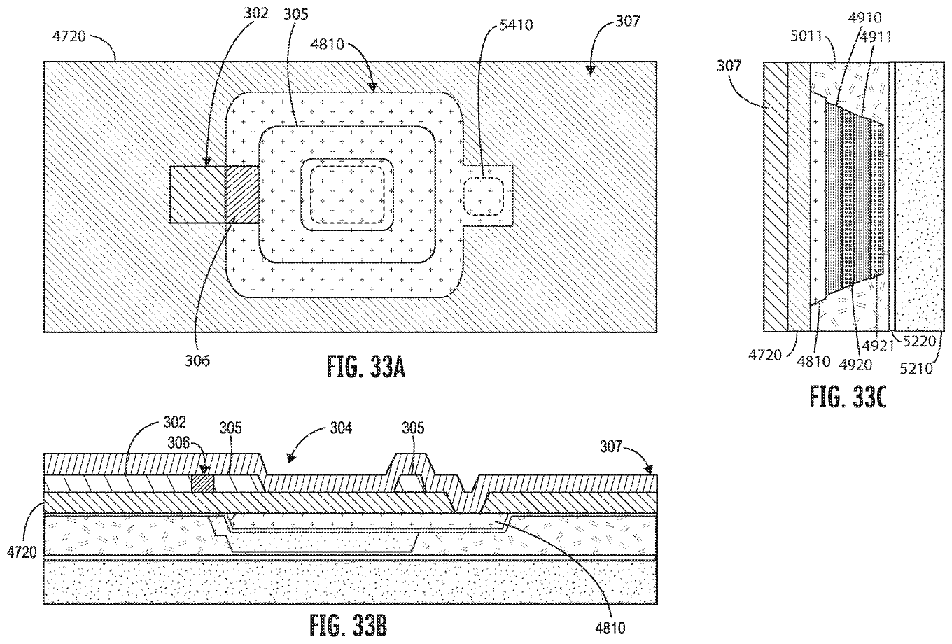

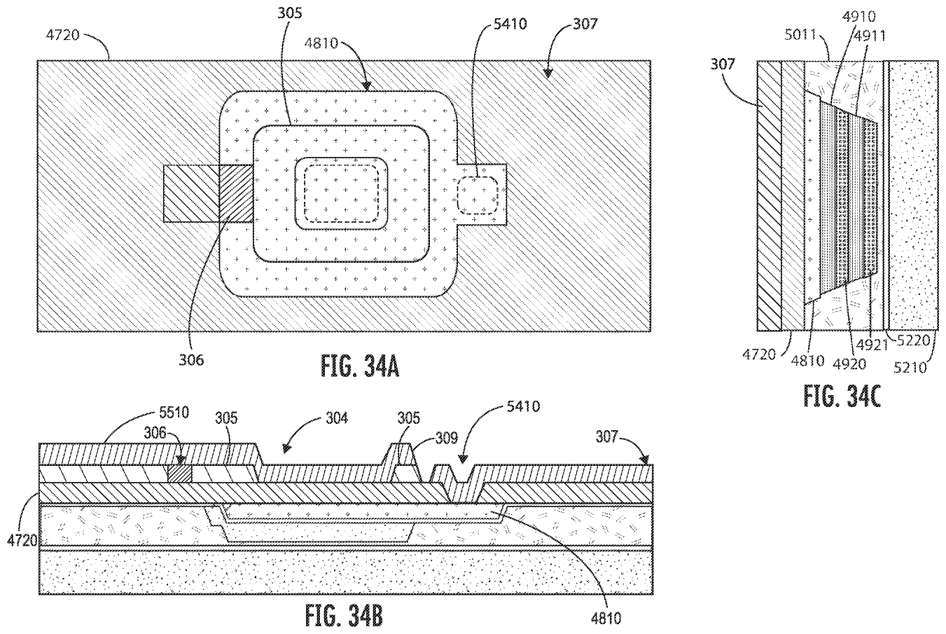

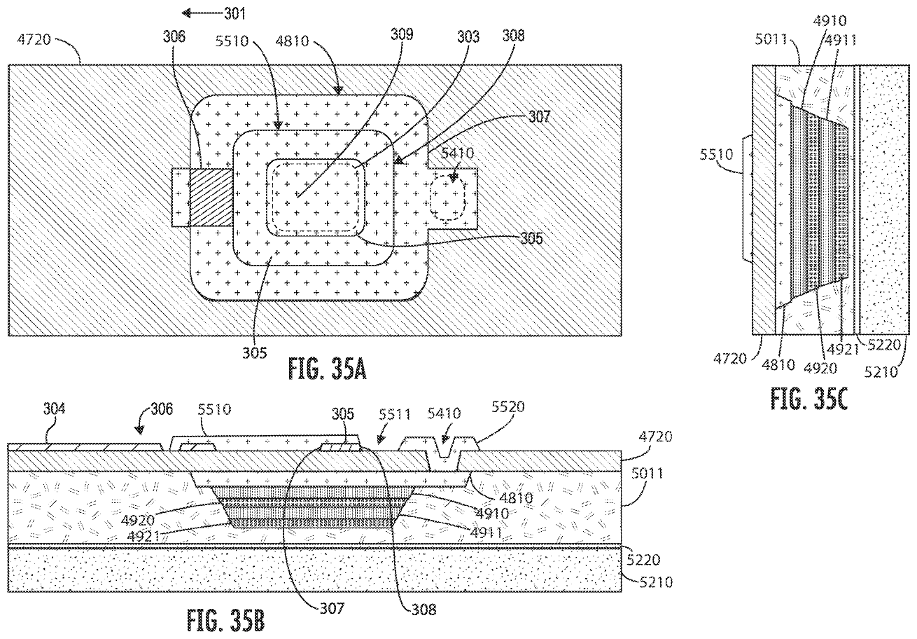

FIGS. 35A-35C are diagrams illustrating various cross-sectional views of a single crystal acoustic resonator device and of operations for a transfer process with a multilayer mirror for single crystal acoustic resonator devices according to an example of the present invention. As shown, these figures illustrate the method of forming a second electrode 5510 overlying the single crystal piezoelectric film 4720 and having the energy confinement frame 305 formed therebetween so that the energy confinement frame 305 is embedded within the second electrode 5510 aligned to the side wall 308 and does not substantially protrude beyond the side wall 308 of the second electrode 5510. In some embodiments according to the present invention, the formation of the second electrode 5510 includes depositing molybdenum (Mo), ruthenium (Ru), tungsten (W), or other like materials; and then etching the second electrode 5510 to remove portion 5511 from the second electrode to form a top metal 5520. Further, the top metal 5520 is physically coupled to the first electrode 5520 through electrode contact via 5410.

As further shown in FIG. 35, the energy confinement layer 304 can be patterned to form the energy confinement frame 305 that is embedded within the second electrode 5520 wherein the outer side wall 308 of the energy confinement frame 305 is aligned to the side wall 308 of the second electrode 5520. Further, in some embodiments according to the present invention, a portion of the energy confinement layer 304 remains outside the first electrode 4810 and extending on the single crystal piezoelectric film 4720 in a direction 301 in which a second electrode contact area will be formed. Still further, in some embodiments according to the present invention, a recess 306 can be formed in the energy confinement layer 304 to separate the remaining energy confinement layer 304 from the energy confinement frame 305. Accordingly, as shown in FIG. 35A, in some embodiments according to the present invention, a recess 306 can be formed to remove a portion of the energy confinement layer 304 so that the portion forms an outer side wall of the energy confinement frame 305 that faces in the direction 301. Accordingly, in such embodiments according to the present invention, the inner and outer side walls 307 and 308 of the energy confinement frame 305 can surround the active region 309.

In other embodiments according to the present invention, the recess 306 is not formed in the energy confinement layer 304 so that the portion 302 of the energy confinement frame 305 is occupied by the energy confinement layer 304 and no outer side wall of the energy confinement frame 305 is formed proximate to the area where the second electrode contact area will be formed, as shown in FIG. 35D.

As further shown in FIG. 35, the energy confinement frame 305 includes the outer side wall 308 and an inner side wall 307 that extend on the surface of the single crystal piezoelectric film 4720 to define a perimeter 303 of the active region 309 of the single crystal piezoelectric film 4720.

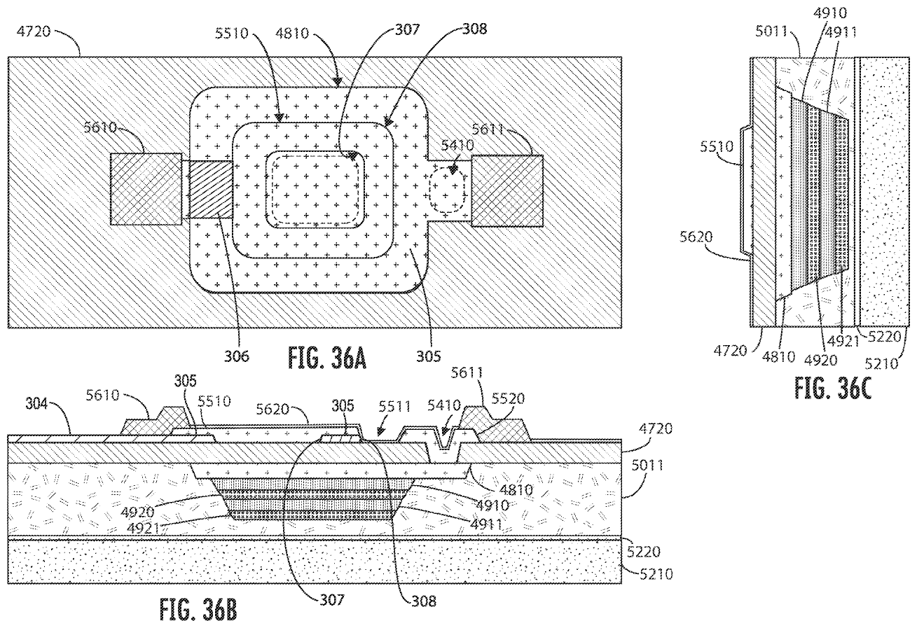

Although FIGS. 36-39 show the resonator devices formed without the recesses 306, it will be understood that those embodiments according to the present invention can be formed using the recess 306 even though not shown in these Figures.

FIGS. 36A-36C are diagrams illustrating various cross-sectional views of a single crystal acoustic resonator device including energy confinement frames and operations for a transfer process with a multilayer mirror for single crystal acoustic resonator devices according to an example of the present invention. As shown, these figures illustrate the method of forming a first contact metal 5610 overlying a portion of the second electrode 5510, a portion of the energy confinement frame 305, and a portion of the single crystal piezoelectric film 4720, and forming a second contact metal 5611 overlying a portion of the top metal 5520 and a portion of the single crystal piezoelectric film 4720. In some embodiments according to the present invention, the first and second contact metals can include gold (Au), aluminum (Al), copper (Cu), nickel (Ni), aluminum bronze (AlCu), or other like materials. This figure also shows the method step of forming a low-impedance acoustic layer 5620 overlying the second electrode 5510, the top metal 5520, and the single crystal piezoelectric film 4720. In some embodiments according to the present invention, the low-impedance acoustic layer 5620 can include silicon nitride (SiN), silicon oxide (SiOx), or other like materials. In some embodiments according to the present invention, the low-impedance acoustic layer 5620 can have a thickness ranging from about 50 nm to about 100 nm. It will be understood that the low-impedance acoustic layer 5620 can have the same thicknesses on the active region and in the outer region outside the active region, in some embodiments according to the invention.

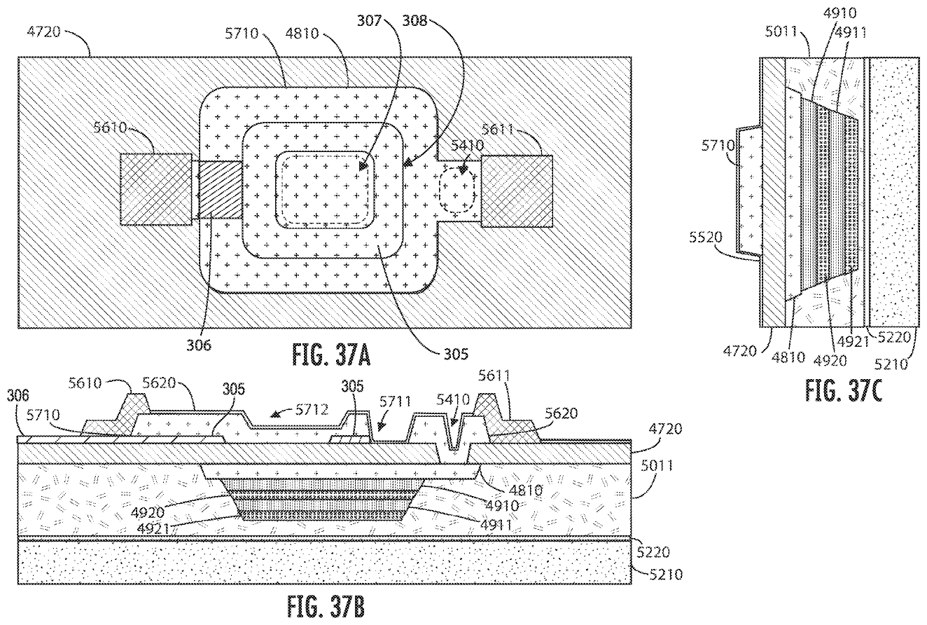

FIGS. 37A-37C are diagrams illustrating various cross-sectional views of a single crystal acoustic resonator device and of operations for a transfer process with a multilayer mirror for single crystal acoustic resonator devices according to another example of the present invention. As shown, these figures illustrate the method step of processing the second electrode 5510 and the top metal 5620 to form a processed second electrode 5710 and a processed top metal 5620. This step can follow the formation of second electrode 5710 and top metal 5720. In some embodiments according to the present invention, the processing of these two components includes depositing molybdenum (Mo), ruthenium (Ru), tungsten (W), or other like materials; and then etching (e.g., dry etch or the like) this material to form the processed second electrode 5410 with an electrode cavity 5712 and the processed top metal 5720. The processed top metal 5720 remains separated from the processed second electrode 5710 by the removal of portion 5711. In some embodiments according to the present invention, this processing gives the second electrode and the top metal greater thickness while creating the electrode cavity 5712. In some embodiments according to the present invention, the processed second electrode 5710 is characterized by the addition of an energy confinement structure configured on the processed second electrode 5710 to increase Q.

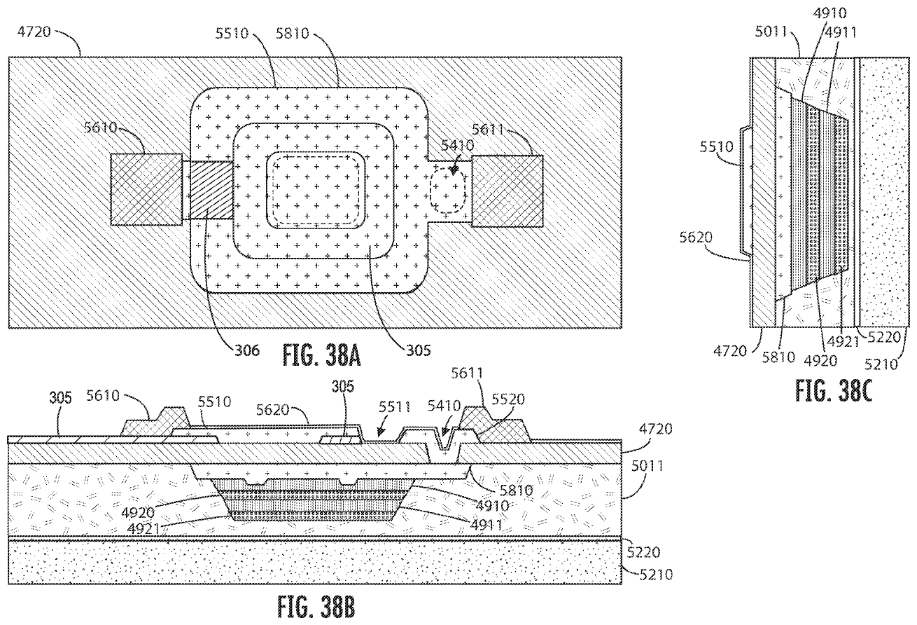

FIGS. 38A-38C are diagrams illustrating various cross-sectional views of a single crystal acoustic resonator device and of operations for a transfer process with a multilayer mirror for single crystal acoustic resonator devices according to another example of the present invention. As shown, these figures illustrate the method step of processing the first electrode 4810 to form a processed first electrode 5810. This step can follow the formation of first electrode 4810. In some embodiments according to the present invention, the processing of these two components includes depositing molybdenum (Mo), ruthenium (Ru), tungsten (W), or other like materials; and then etching (e.g., dry etch or the like) this material to form the processed first electrode 5810 with an electrode cavity, similar to the processed second electrode 5710. Compared to previous examples, there is no air cavity. In some embodiments according to the present invention, the processed first electrode 5810 is characterized by the addition of an energy confinement structure configured on the processed second electrode 5810 to increase Q.

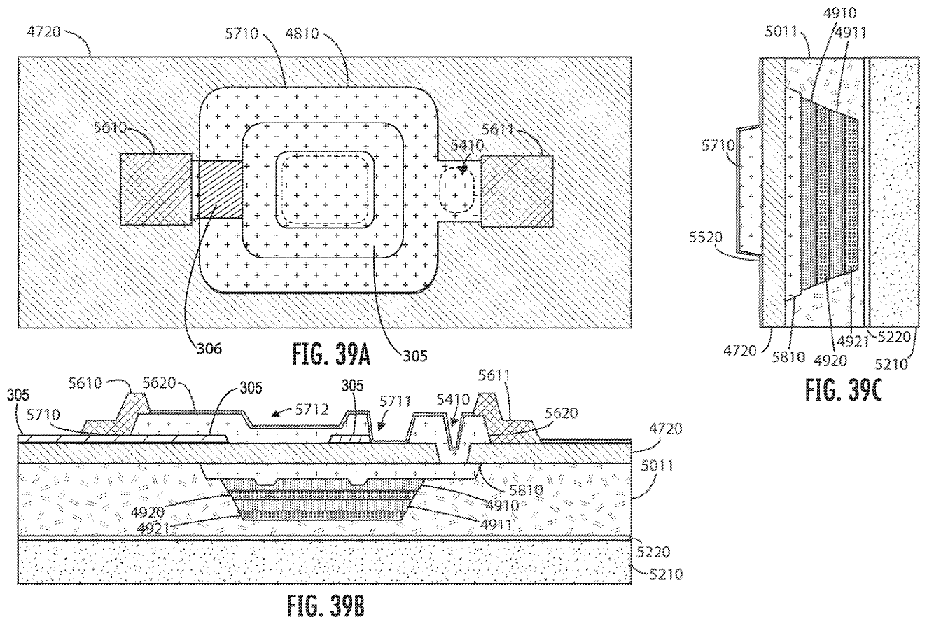

FIGS. 39A-39C are diagrams illustrating various cross-sectional views of a single crystal acoustic resonator device and of operations for a transfer process with a multilayer mirror for single crystal acoustic resonator devices according to another example of the present invention. As shown, these figures illustrate the method step of processing the first electrode 4810, to form a processed first electrode 5810, and the second electrode 5510/top metal 5520 to form a processed second electrode 5710/processed top metal 5620. These steps can follow the formation of each respective electrode, as described for FIGS. 57A-57C and 58A-58C. Those of ordinary skill in the art will recognize other variations, modifications, and alternatives.

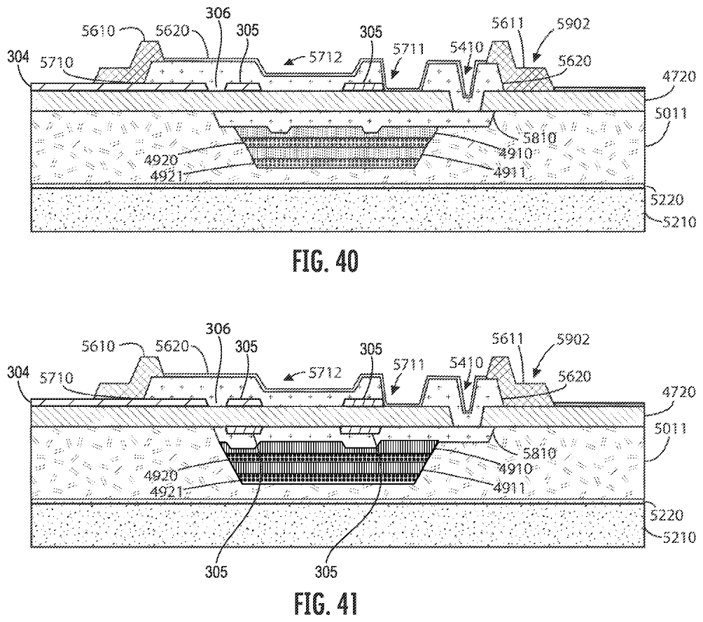

FIG. 40 is a cross-sectional view of a piezoelectric resonator device including an energy confinement frame 305 in some embodiment according to the present invention. As shown in FIG. 40, the energy confinement frame 305 is located on the single crystal piezoelectric film 4720 beneath the second electrode 5710. Furthermore, in some embodiments according to the present invention, the energy confinement frame 305 defines the perimeter within which the active region of the piezoelectric resonator device is located whereas the outer region, beyond the energy confinement frame 905, includes the area outside the active region of the piezoelectric resonator device, as shown. In some embodiments according to the present invention, the energy confinement layer 304 can be formed of SiO₂ and can have a thickness in a range between about 200 Angstroms and about 2000 Angstroms, and preferably have a thickness in a range between about 600 Angstroms and about 1000 Angstroms. In some embodiments according to the present invention, the energy confinement frame 305 can have substantially the same thickness as the energy confinement layer 304 and may vary due to, for example, the effects of processing the layers and structures as described herein.

In some embodiments according to the present invention, the low-impedance acoustic layer 5620 can have a conformal profile on the second electrode 5510 to extend over the active region and over the energy confinement frame 305 onto the side wall 308 of the second electrode 5510 and onto the directly adjacent portion of the single crystal piezoelectric film 4720 in the outer region. Accordingly, the portion of the low-impedance acoustic layer 5620 over the active region can have substantially the same thickness as the portion of the low-impedance acoustic layer 5620 on the directly adjacent portion of the single crystal piezoelectric film 4720. In some embodiments according to the present invention, the low-impedance acoustic layer 5620 can be formed of SiN to have a thickness in a range between about 100 Angstroms and about 3000 Angstroms.

As further shown, in some embodiments according to the present invention, the energy confinement layer 304 can extend on the single crystal piezoelectric film 4720 beyond the energy confinement frame 305 into the outer region on the side of the piezoelectric resonator device that includes the contact area ohmically coupled to the second electrode 5510. In contrast, in some embodiments according to the present invention, the energy confinement layer 304 on the side of the piezoelectric resonator device that includes the contact area ohmically coupled to the first electrode 5810 is confined to beneath the second electrode 5510 and does not extend beyond the side wall 308 as the energy confinement layer 904 on the directly adjacent portion of the single crystal piezoelectric film 1621, has been removed prior to formation of the low-impedance acoustic layer 5620.

In some embodiments according to the present invention, the portion of the energy confinement frame 305 on the side of the piezoelectric resonator device that includes the contact area ohmically coupled to the first electrode 5810 has a cross-section width in a range between about 0.1 micrometers and about 10 micrometers. In some embodiments according to the present invention, the recess 306 can be formed in the energy confinement layer 304 so that the resulting portion of the energy confinement frame 905 on the side of the piezoelectric resonator device that includes the contact area ohmically coupled to the second electrode 2510 has a cross-section width in a range between about 0.1 micrometers and about 10 micrometers.

FIG. 41 is a cross-sectional view of a piezoelectric resonator device including first and second energy confinement frames 305 respectively located on the lower surface and the upper surface of the single crystal piezoelectric film 4720 in some embodiment according to the present invention. As shown in FIG. 41, the energy confinement frames 305 are located between the upper surface of the single crystal piezoelectric film 4720 and the second electrode 5710 and located between the lower surface of the single crystal piezoelectric film 4720 and the first electrode 5810. In some embodiments according to the invention, the first and second energy confinement frames 305 are aligned with one another to define the active region of the piezoelectric resonator device. In some embodiments according to the invention, the first and second energy confinement layers 304 can include a recess 306 to define the respective first and second energy confinement frame 305. Accordingly, in some embodiments according to the invention, either or both of the first and second energy confinement frames 305 may be formed using the recess 306. Still further, in some embodiments according to the invention, the second energy confinement frames 305 of FIG. 41 can have substantially the same thicknesses and be formed of the same materials as described herein.

Although FIGS. 40 and 41 show the resonator devices formed with the recesses 306, it will be understood that these embodiments according to the present invention can be formed without the recess 306 even though not shown. It will be understood that that, in some embodiments according to the invention, the surface of the first processed electrode 5810 can be planar.

In each of the preceding examples relating to transfer processes, energy confinement structures can be formed on the first electrode, second electrode, or both. In some embodiments according to the present invention, these energy confinement structures are mass loaded areas surrounding the resonator area. The resonator area is the area where the first electrode, the piezoelectric layer, and the second electrode overlap. The larger mass load in the energy confinement structures lowers a cut-off frequency of the resonator. The cut-off frequency is the lower or upper limit of the frequency at which the acoustic wave can propagate in a direction parallel to the surface of the single crystal piezoelectric film. Therefore, the cut-off frequency is the resonance frequency in which the wave is travelling along the thickness direction and thus is determined by the total stack structure of the resonator along the vertical direction. In piezoelectric films (e.g., AlN), acoustic waves with lower frequency than the cut-off frequency can propagate in a parallel direction along the surface of the film, i.e., the acoustic wave exhibits a high-band-cut-off type dispersion characteristic. In this case, the mass loaded area surrounding the resonator provides a barrier preventing the acoustic wave from propagating outside the resonator. By doing so, this feature increases the quality factor of the resonator and improves the performance of the resonator and, consequently, the filter.

In addition, the single crystalline piezoelectric layer can be replaced by a polycrystalline piezoelectric film. In such films, the lower part that is close to the interface with the substrate may have lower crystalline quality with smaller grain sizes and a wider distribution of the piezoelectric polarization orientation than the upper part of the film close to the surface. Considering AlN as a piezoelectric material, the growth rate along the c-axis or the polarization orientation may be higher than other crystalline orientations that can increase the proportion of the grains with the c-axis perpendicular to the growth surface as the film grows thicker. In some embodiments, a polycrystalline AlN film with about a 1 um thickness, the upper part of the film close to the surface may have higher crystalline quality and better alignment in terms of piezoelectric polarization. By using the thin film transfer process described herein, it is possible to use the upper portion of the polycrystalline film in high frequency BAW resonators with very thin piezoelectric films. This can be done by removing a portion of the piezoelectric layer during the growth substrate removal process.

The piezoelectric materials or films referred to in each of the preceding examples can include single crystal materials/films, epitaxial materials/films, textured materials/films, polycrystalline materials/films, or combinations thereof. The piezoelectric materials can also include a substantially single crystal material that exhibits certain polycrystalline qualities, i.e., an essentially single crystal material. In a specific example, the first, second, third, and fourth piezoelectric materials are each essentially a single crystal aluminum nitride (AlN) bearing material or aluminum scandium nitride (AlScN) bearing material, a single crystal gallium nitride (GaN) bearing material or gallium aluminum nitride (GaAlN) bearing material, a magnesium hafnium aluminum nitride (MgHfAlN) material, or the like. In other specific examples, these piezoelectric materials each comprise a polycrystalline aluminum nitride (AlN) bearing material or aluminum scandium nitride (AlScN) bearing material, or a polycrystalline gallium nitride (GaN) bearing material or gallium aluminum nitride (GaAlN) bearing material, a magnesium hafnium aluminum nitride (MgHfAlN) material, or the like. In other examples, the piezoelectric materials can include aluminum gallium nitride (AlxGa1-xN) material, or an aluminum scandium nitride (AlxSc1-xN) material characterized by a composition of 0≤X<1.0. As discussed previously, the thicknesses of the piezoelectric materials can vary, and in some cases can be greater than 250 nm.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. Additionally, as used herein, the term “and/or” includes any and all combinations of one or more of the associated listed items and may be abbreviated as “/”.

The term “comprise,” as used herein, in addition to its regular meaning, may also include, and, in some embodiments, may specifically refer to the expressions “consist essentially of” and/or “consist of.” Thus, the expression “comprise” can also refer to, in some embodiments, the specifically listed elements of that which is claimed and does not include further elements, as well as embodiments in which the specifically listed elements of that which is claimed may and/or does encompass further elements, or embodiments in which the specifically listed elements of that which is claimed may encompass further elements that do not materially affect the basic and novel characteristic(s) of that which is claimed. For example, that which is claimed, such as a composition, formulation, method, system, etc. “comprising” listed elements also encompasses, for example, a composition, formulation, method, kit, etc. “consisting of,” i.e., wherein that which is claimed does not include further elements, and a composition, formulation, method, kit, etc. “consisting essentially of,” i.e., wherein that which is claimed may include further elements that do not materially affect the basic and novel characteristic(s) of that which is claimed.

The term “about” generally refers to a range of numeric values that one of skill in the art would consider equivalent to the recited numeric value or having the same function or result. For example, “about” may refer to a range that is within ±1%, ±2%, ±5%, ±7%, ±10%, ±15%, or even ±20% of the indicated value, depending upon the numeric values that one of skill in the art would consider equivalent to the recited numeric value or having the same function or result. Furthermore, in some embodiments, a numeric value modified by the term “about” may also include a numeric value that is “exactly” the recited numeric value. In addition, any numeric value presented without modification will be appreciated to include numeric values “about” the recited numeric value, as well as include “exactly” the recited numeric value. Similarly, the term “substantially” means largely, but not wholly, the same form, manner or degree and the particular element will have a range of configurations as a person of ordinary skill in the art would consider as having the same function or result. When a particular element is expressed as an approximation by use of the term “substantially,” it will be understood that the particular element forms another embodiment.

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall support claims to any such combination or subcombination.

What is claimed:

1. A method of forming a piezoelectric resonator device, the method comprising:
forming a piezoelectric film on a growth substrate;
forming a first electrode on a first surface of the piezoelectric film;
forming a support layer on the piezoelectric film and on the first electrode;
bonding the support layer to a bond substrate;
removing the growth substrate to expose a second surface of the piezoelectric film that is opposite the first surface of the piezoelectric film;
forming an energy confinement layer on the second surface of the piezoelectric film;
patterning the energy confinement layer to form an energy confinement frame on a portion of the second surface of the piezoelectric film designated as the active region of the piezoelectric resonator device, the energy confinement frame including an outer side wall that faces an outer region of the piezoelectric film outside the active region and an including an inner side wall that extends around a permitter of the active region;
forming a second electrode layer extending on the active region conformably over the energy confinement frame onto the outer side wall and onto a portion of the piezoelectric film in the outer region directly adjacent to the energy confinement frame;
forming a second electrode on the second surface of the piezoelectric film by removing the second electrode layer and the energy confinement layer from the portion of the piezoelectric film in the outer region directly adjacent to the energy confinement frame so that the outer side wall of the energy confinement frame is aligned with a side wall of the second electrode; and
forming a substantially uniform thickness low-impedance acoustic layer over the active area and onto the side wall of the second electrode and onto the portion of the piezoelectric film in the outer region directly adjacent to the energy confinement frame.

2. The method of claim 1 wherein forming the support layer is preceded by forming a sacrificial layer on the first electrode, the method further comprising:
removing the sacrificial layer to form a cavity beneath the first electrode opposite the active region.

3. The method of claim 1 wherein forming the support layer is preceded by forming a multi-layered reflector on the first electrode.

4. The method of claim 1 wherein patterning the energy confinement layer further comprises forming a recess in the energy confinement layer proximate to where a second electrode contact area is to be formed to separate a remaining portion of the energy confinement layer that extends away from the second electrode contact area from the outer side wall of the energy confinement frame.

5. The method of claim 1 wherein forming the energy confinement layer further comprises forming the energy confinement layer to a thickness in a range between about 600 Angstroms and about 1000 Angstroms.

6. The method of claim 1 wherein the energy confinement frame comprises SiO2.

7. The method of claim 1 wherein the energy confinement frame comprises a metal.

8. The method of claim 7 wherein the metal comprises tungsten and/or molybdenum.

9. The method of claim 7 wherein the metal has a density in a range between about 2.7 g/cm³ and about 20 g/cm³.

10. The method of claim 1 wherein the energy confinement frame comprises a low-density material.

11. The method of claim 10 wherein the low-density material has a density in a range between about 2.65 g/cm³ and about 3.26 g/cm³.

12. The method of claim 10 wherein the low-density material comprises AlN, ScAlN, SiO₂, and/or SiN.

13. The method of claim 1 where the piezoelectric film comprises a single crystal piezoelectric film.

14. The method of claim 1 where the piezoelectric film comprises a polycrystalline piezoelectric film.
